(19) United States
(12) Patent Application Publication
(10) Pub. No.: US 2026/0150290 A1
(43) Pub. Date: May 28, 2026

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Wooyong Jeon, Suwon-si (KR); Youngwoo Kim, Suwon-si (KR); Seonyoung Min, Suwon-si (KR); Gyuwon Byun, Suwon-si (KR)

(21) Appl. No.: 19/348,744

(22) Filed: Oct. 2, 2025

(30) Foreign Application Priority Data
Nov. 22, 2024 (KR) 10-2024-0168576

(51) Int. Cl. H10B 43/27; H10B 43/10; H10B 43/40

(52) U.S. Cl. CPC H10B 43/27; H10B 43/10; H10B 43/40

(57) ABSTRACT

A three-dimensional semiconductor memory device may include a substrate including a cell array region and a connection region, a stack including insulating layers and gate electrodes alternatingly stacked on the substrate, a vertical structure provided on the cell array region to penetrate the stack, a gate contact provided on the connection region to penetrate the stack, an upper insulating layer on the stack, and a device isolation pattern in the upper insulating layer. The gate contact may penetrate at least a portion of the device isolation pattern.

### CROSS-REFERENCE TO RELATED APPLICATION(S)

This U.S. non-provisional patent application claims priority to Korean Patent Application No. 10-2024-0168576, filed in the Korean Intellectual Property Office on November 22, 2024, the disclosure of which is hereby incorporated by reference in its entirety.

### BACKGROUND

A semiconductor device capable of storing a large amount of data is used as a data storage of an electronic system. Higher integration of semiconductor devices is desired to satisfy consumer demands for large data storing capacity, superior performance, and inexpensive prices. In the case of two-dimensional or planar semiconductor devices, since their integration is mainly determined by the area occupied by a unit memory cell, integration is greatly influenced by the level of a fine pattern forming technology. However, the extremely expensive process equipment needed to increase pattern fineness sets a practical limitation on increasing integration for two-dimensional or planar semiconductor devices. Thus, three-dimensional semiconductor memory devices including three-dimensionally arranged memory cells have recently been proposed.

### SUMMARY

In general, the present disclosure is directed toward a three-dimensional semiconductor memory device with improved electrical and reliability characteristics, and an electronic system including a three-dimensional semiconductor memory device with improved electrical and reliability characteristics.

According to some implementations, the present disclosure is directed to a three-dimensional (3D) semiconductor memory device that includes a substrate including a cell array region and a connection region, a stack including insulating layers and gate electrodes alternatingly stacked on the substrate, a vertical structure provided on the cell array region to penetrate the stack, a gate contact provided on the connection region to penetrate the stack, an upper insulating layer on the stack, and a device isolation pattern in the upper insulating layer. The gate contact may penetrate at least a portion of the device isolation pattern.

According to some implementations, the present disclosure is directed to a three-dimensional (3D) semiconductor memory device that includes a substrate including a cell array region and a connection region, which is extended from the cell array region in a first direction, a stack provided on the substrate, the stack including a first block and a second block, which are spaced apart from each other in a second direction crossing the first direction, vertical structures provided on the cell array region to penetrate the stack, an upper insulating layer on the stack, a first gate contact provided on the connection region to penetrate a portion of the first block of the stack, and a second gate contact provided on the connection region to penetrate the second block of the stack. A length of the second gate contact may be larger than a length of the stack, when measured in a third direction crossing the first and second directions.

According to some implementations, the present disclosure is directed to an electronic system that includes a three-dimensional semiconductor memory device including input/output pads electrically connected to peripheral transistors, and a controller, which is electrically connected to the three-dimensional semiconductor memory device through the input/output pads and is configured to control the three-dimensional semiconductor memory device. The three-dimensional semiconductor memory device may include a substrate including a cell array region and a connection region, a stack including gate electrodes stacked on the substrate, vertical structures provided on the cell array region to penetrate the stack, and a first gate contact and a second gate contact on the connection region of the substrate. The first gate contact may be provided to penetrate a portion of the stack and may be connected to one of the gate electrodes, and the second gate contact may be provided to penetrate the stack and may be connected to one of the input/output pads. The first gate contact and the second gate contact may be aligned along a first surface of the stack.

### BRIEF DESCRIPTION OF THE DRAWINGS

Example implementations will be more clearly understood from the following detailed description, taken in conjunction with the accompanying drawings.

FIG. 1 is a schematic diagram illustrating an example of an electronic system including a three-dimensional semiconductor memory device according to some implementations.

FIG. 2 is a perspective view schematically illustrating an example of an electronic system including a three-dimensional semiconductor memory device according to some implementations.

FIGS. 3 and 4 are sectional views taken along a line I-I’ of FIG. 2 illustrating an example of a semiconductor package including a three-dimensional semiconductor memory device according to some implementations.

FIG. 5 is a plan view illustrating an example of a three-dimensional semiconductor memory device, according to some implementations.

FIGS. 6A and 6B are sectional views taken along lines A-A' and B-B' of FIG. 5 illustrating an example of a three-dimensional semiconductor memory device according to some implementations.

FIG. 7 is an enlarged sectional view illustrating an example of a portion (e.g., X of FIG. 6A) of a three-dimensional semiconductor memory device according to some implementations.

FIG. 8 is an enlarged sectional view illustrating an example of a portion (e.g., Y of FIG. 6B) of a three-dimensional semiconductor memory device according to some implementations.

FIGS. 9A and 9B are enlarged sectional views illustrating an example of a portion (e.g., Z of FIG. 6B) of a three-dimensional semiconductor memory device according to some implementations.

FIGS. 10A to 16B are sectional views illustrating an example of a method of fabricating a three-dimensional semiconductor memory device according to some implementations.

### DETAILED DESCRIPTION

Hereinafter, example implementations will be explained in detail with reference to the accompanying drawings.

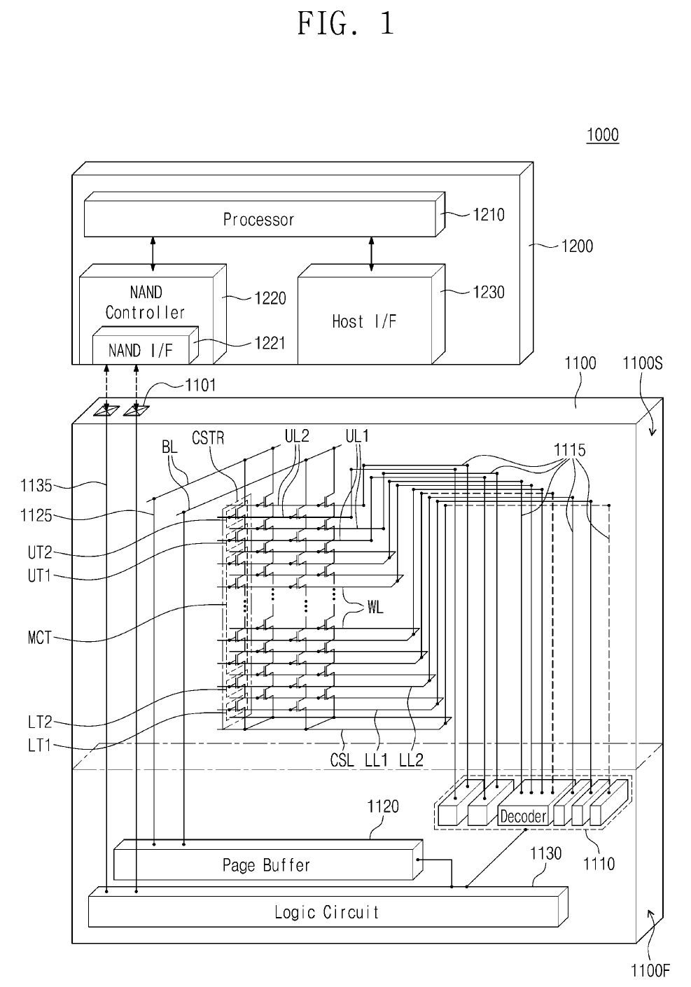

FIG. 1 is a schematic diagram illustrating an example of an electronic system including a three-dimensional semiconductor memory device according to some implementations. In FIG. 1, an electronic system 1000 may include a three-dimensional semiconductor memory device 1100 and a controller 1200, which is electrically connected to the three-dimensional semiconductor memory device 1100. The electronic system 1000 may be a storage device including the three-dimensional semiconductor memory device 1100 or an electronic device including a storage device. For example, the electronic system 1000 may be a solid state drive (SSD) device, a universal serial bus (USB), a computing system, a medical system, or a communication system, in which the three-dimensional semiconductor memory device 1100 is provided. In some implementations, a plurality of three-dimensional semiconductor memory devices 1100 may be provided.

The three-dimensional semiconductor memory device 1100 may be a nonvolatile memory device (e.g., a NAND FLASH memory device). The three-dimensional semiconductor memory device 1100 may include a first structure 1100F and a second structure 1100S on the first structure 1100F. In some implementations, the first structure 1100F may be disposed beside the second structure 1100S.

The first structure 1100F may be a peripheral circuit structure, which includes a decoder circuit 1110, a page buffer 1120, and a logic circuit 1130. The second structure 1100S may be a memory cell structure, which includes bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include an lower transistors LT1 and LT2 adjacent to the common source line CSL, upper transistors UT1 and UT2 adjacent to the bit lines BL, and memory cell transistors MCT disposed between the lower transistors LT1 and LT2 and the upper transistors UT1 and UT2.

In some implementations, each of the memory cell transistors MCT may include a data storing element having a ferroelectric material. By using the data storing element with the ferroelectric material, it may be possible to realize a three-dimensional semiconductor memory device that can be operated with low power and with a fast operation speed. In this case, a voltage difference between the word lines WL and channel regions of the memory cell transistors MCT may be adjusted to cause a change in polarization of a dipole of the ferroelectric material, and this may be used to write or erase data in the memory cell transistors MCT.

In some implementations, each of the memory cell transistors MCT may be an Electrochemical Random Access Memory (ECRAM) device, which contains a data storing element with a solid electrolyte and an ion storage. By using the data storing element with the solid electrolyte and the ion storage, it may be possible to realize a three-dimensional semiconductor memory device that can be operated with low power and with a fast operation speed. In this case, a voltage difference between the word lines WL and the channel regions of the memory cell transistors MCT may be adjusted to change the electric resistance of the channel regions of the memory cell transistors MCT, and this may be used to write or erase data in the memory cell transistors MCT.

For example, the upper transistors UT1 and UT2 may include a string selection transistor, and the lower transistors LT1 and LT2 may include a ground selection transistor. The gate lower lines LL1 and LL2 may be used as gate electrodes of the lower transistors LT1 and LT2, respectively. The gate upper lines UL1 and UL2 may be used as respective gate electrodes of the upper transistors UT1 and UT2. In some implementations, the number of the lower transistors LT1 and LT2 and the number of the upper transistors UT1 and UT2 may be variously changed.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may execute a control operation on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The first structure 1100F may further include a voltage generator. The voltage generator may generate a program voltage, a read voltage, a pass voltage, a verify voltage, and so forth, which are needed to operate the memory cell strings CSTR. Here, the program voltage may be a relatively high voltage (e.g., 20V to 40V), compared with the read voltage, the pass voltage, and the verify voltage.

In some implementations, the first structure 1100F may include high-voltage transistors and low-voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface 1230. In some implementations, a plurality of three-dimensional semiconductor memory devices 1100 may be provided, and the controller 1200 may be configured to control the three-dimensional semiconductor memory devices 1100.

The processor 1210 may control overall operations of the electronic system 1000 including the controller 1200. Based on a specific firmware, the processor 1210 may be configured to execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which will be used to control the three-dimensional semiconductor memory device 1100 and data, which will be written in or read from the memory cell transistors MCT. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

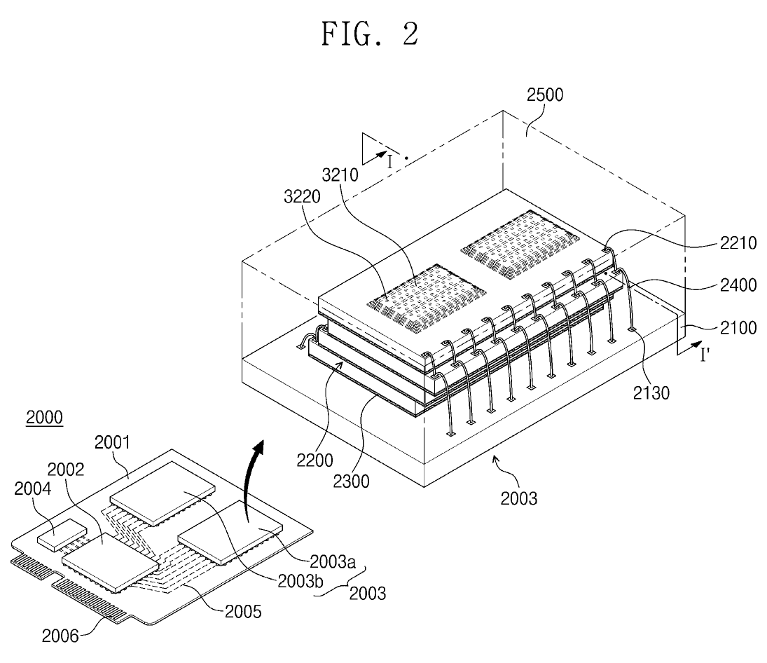

FIG. 2 is a perspective view schematically illustrating an example of an electronic system including a three-dimensional semiconductor memory device according to some implementations. In FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In some implementations, the electronic system 2000 may be driven by an electric power, which is supplied from the external host through the connector 2006. The electronic system 2000 may further include a power management integrated circuit (PMIC) that is configured to separately supply an electric power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In some implementations, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacks 3210 and vertical structures 3220. Each of the semiconductor chips 2200 may include a three-dimensional semiconductor memory device, which will be described below.

For example, the connection structure 2400 may be a bonding wire electrically connecting the input/output pad 2210 to the upper pads 2130. Accordingly, in each of the first and second semiconductor packages 2003a and 2003b, the semiconductor chips 2200 may be electrically connected to each other in a bonding wire manner and may be electrically connected to the upper pads 2130 of the package substrate 2100. In some implementations, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In some implementations, the controller 2002 and the semiconductor chips 2200 may be included in a single package, but the inventive concept is not limited to this example. For example, the controller 2002 and the semiconductor chips 2200 may be mounted on a separate interposer substrate, which is prepared regardless of the main substrate 2001, and may be connected to each other through interconnection lines, which are provided in the interposer substrate.

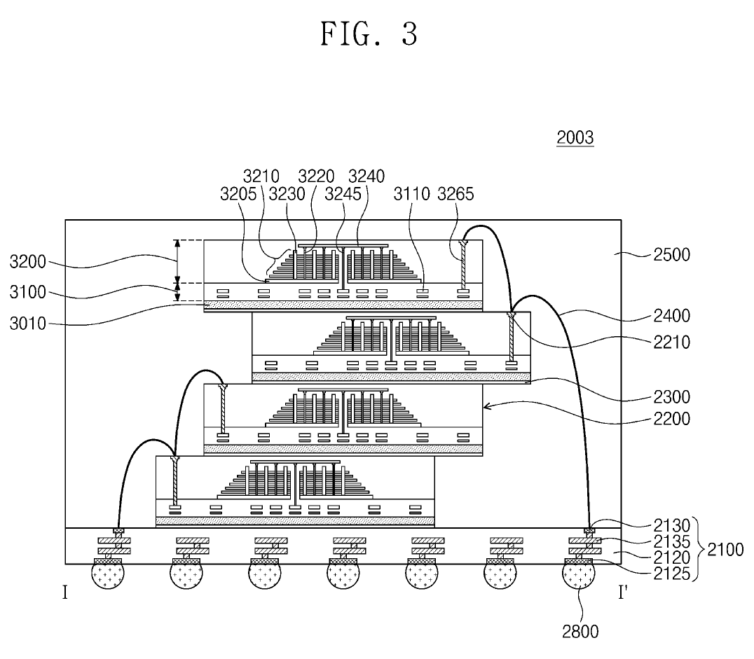

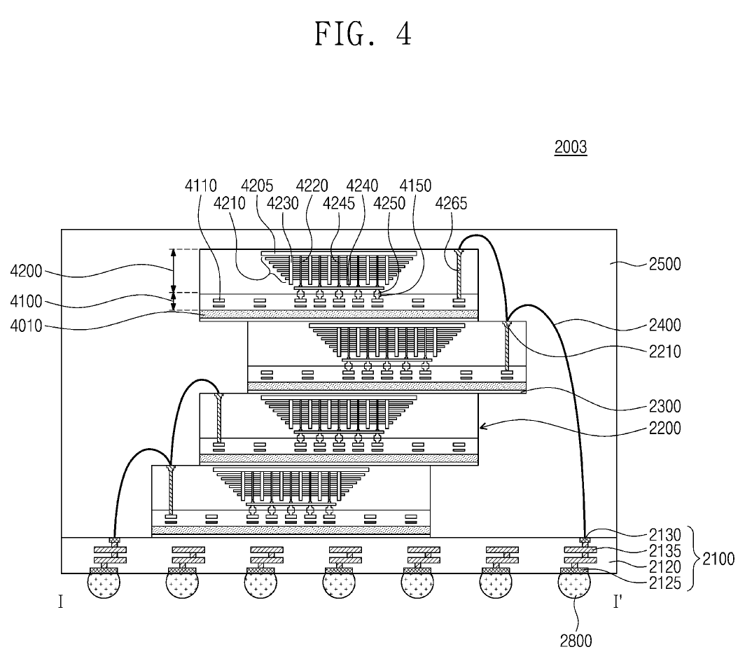

FIGS. 3 and 4 are sectional views taken along a line I-I’ of FIG. 2 illustrating an example of a semiconductor package including a three-dimensional semiconductor memory device according to some implementations. In FIG. 3, the package substrate 2100 in the semiconductor package 2003 may be a printed circuit board. The package substrate 2100 may include a package substrate body 2120, upper pads 2130, which are disposed on a top surface of the package substrate body 2120, lower pads 2125, which are disposed on or exposed through a bottom surface of the package substrate body 2120, and internal lines 2135, which are disposed in the package substrate body 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region provided with peripheral lines 3110. The second structure 3200 may include a source structure 3205, a stack 3210 on the source structure 3205, vertical structures 3220 and separation structures 3230, which are provided to penetrate the stack 3210, bit lines 3240, which are electrically connected to the vertical structures 3220, and cell contact plugs 3235, which are electrically connected to the word lines WL (e.g., see FIG. 1) of the stack 3210.

Each of the semiconductor chips 2200 may be electrically connected to the peripheral lines 3110 of the first structure 3100 and may include penetration lines 3245, which is extended into the second structure 3200. The penetration lines 3245 may be disposed outside the stack 3210 and may be further extended to penetrate the stack 3210. Each of the semiconductor chips 2200 may further include the input/output pad 2210 electrically connected to the peripheral lines 3110 of the first structure 3100.

In FIG. 4, the semiconductor chips 2200 of the semiconductor package 2003 may include a semiconductor substrate 4010, a first structure 4100, which is placed on the semiconductor substrate 4010, and a second structure 4200, which is placed on the first structure 4100 and is bonded to the first structure 4100 in a wafer bonding manner.

The first structure 4100 may include a peripheral circuit region, which includes a peripheral interconnection 4110 and first junction structures 4150. The second structure 4200 may include a source structure 4205, a stack 4210 between the source structure 4205 and the first structure 4100, vertical structures 4220 and separation structure 4230 penetrating the stack 4210, and second junction structures 4250, which are electrically connected to the vertical structures 4220 and the word lines WL (e.g., FIG. 1) of the stack 4210. For example, the second junction structures 4250 may be electrically connected to the vertical structures 4220 and the word lines WL of FIG. 1, respectively, through bit lines 4240 and cell contact plugs 4235 that are electrically connected to the vertical structures 4220 and the word lines WL of FIG. 1. The first junction structures 4150 of the first structure 4100 and the second junction structures 4250 of the second structure 4200 may be in contact with each other and may be bonded to each other. For example, the first junction structures 4150 and the second junction structures 4250 may include copper (Cu).

In FIGS. 3 and 4, the first structure 3100 or 4100 and the second structure 3200 or 4200 may correspond to the first structure 1100F and the second structure 1100S of FIG. 1. The semiconductor chips 2200 may be electrically connected to each other by the connection structures 2400, which are provided in the form of bonding wires, but the inventive concept is not limited to this example. For example, the semiconductor chips 2200 may be electrically connected to each other by penetration electrodes penetrating the semiconductor chips 2200.

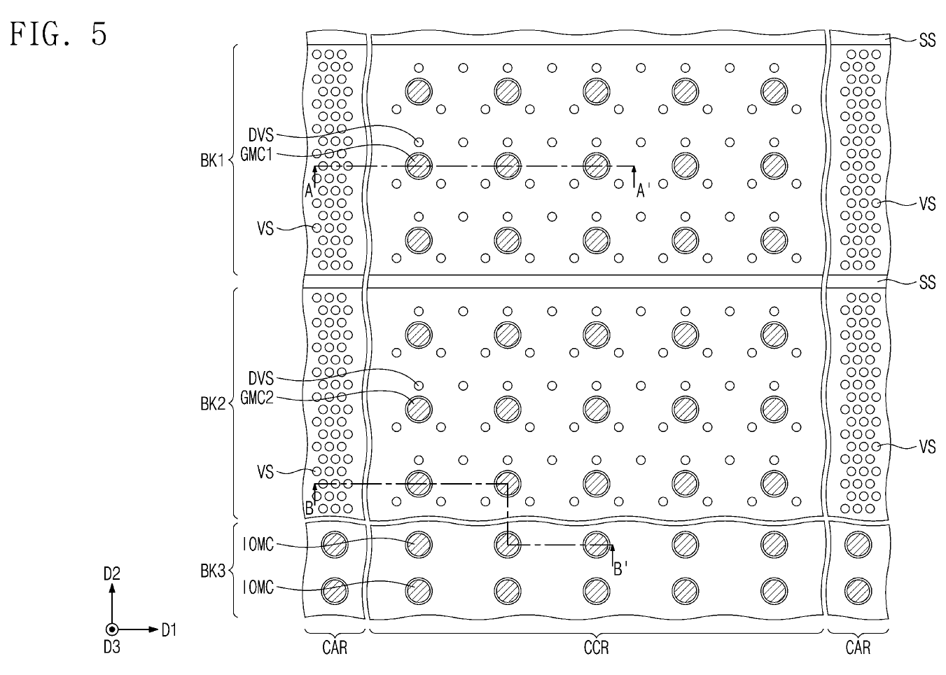

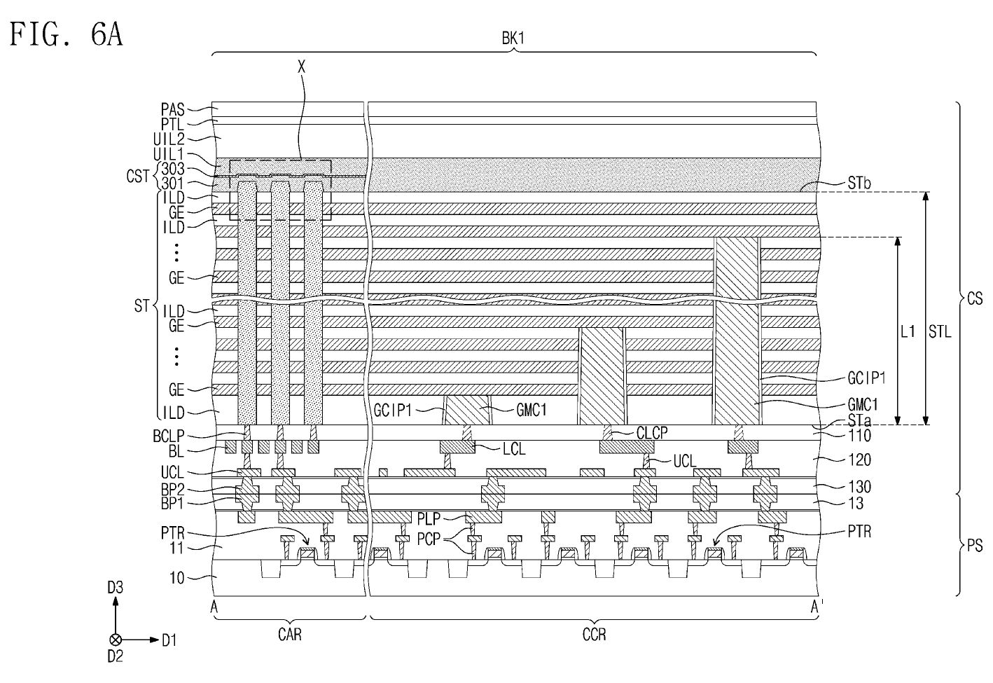

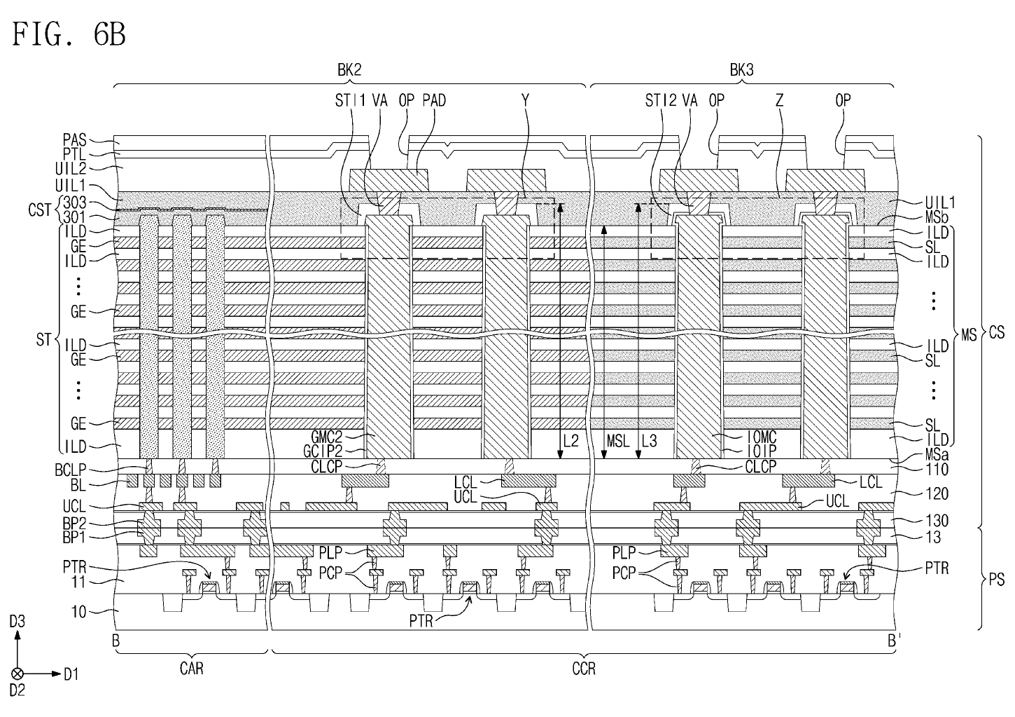

FIG. 5 is a plan view illustrating an example of a three-dimensional semiconductor memory device according to some implementations. FIGS. 6A and 6B are sectional views taken along lines A-A' and B-B' of FIG. 5 illustrating an example of a three-dimensional semiconductor memory device according to some implementations.

In FIGS. 5, 6A, and 6B, a three-dimensional semiconductor memory device may include a peripheral circuit structure PS and a cell array structure CS, which are sequentially stacked on a substrate 10. For example, the substrate 10 may correspond to the semiconductor substrate 3010 or 4010 of FIGS. 3 or 4. The peripheral circuit structure PS may correspond to the first structure 3100 or 4100 of FIGS. 3 or 4. The cell array structure CS may correspond to the second structure 3200 or 4200 of FIGS. 3 or 4.

In some implementations, since the cell array structure CS is bonded to the peripheral circuit structure PS, it may be possible to increase the cell capacity per unit area of the three-dimensional semiconductor memory device. In addition, the peripheral circuit structure PS and the cell array structure CS may be separately fabricated and then may be coupled to each other, and in this case, it may be possible to prevent peripheral transistors PTR from being damaged by several thermal treatment processes. Accordingly, the electrical and reliability characteristics of the three-dimensional semiconductor memory device may be improved.

The substrate 10 may be one of a silicon substrate, a silicon-germanium substrate, a germanium substrate, and a structure including a single-crystalline silicon substrate and a single-crystalline epitaxial layer grown therefrom, but the present disclosure is not limited to this example. A top surface of the substrate 10 may be parallel to a first direction D1 and a second direction D2, which are not parallel to each other. The top surface of the substrate 10 may be normal to a third direction D3. Here, the first to third directions D1, D2, and D3 may be orthogonal to each other. In the present disclosure, the first and second directions D1 and D2 may be referred to as horizontal directions, and the third direction D3 may be referred to as a vertical direction.

The substrate 10 may include a cell array region CAR and a connection region CCR, which is adjacent to the cell array region CAR and is extended in the first direction D1. The cell array region CAR may be, for example, a region, on which vertical structures VS to be described below are provided. The connection region CCR may be a region, on which first and second gate contacts GMC1 and GMC2 to be described below provided. In some implementations, a plurality of cell array regions CAR may be provided, and the connection region CCR may be placed therebetween.

The peripheral circuit structure PS may include peripheral transistors PTR and peripheral plugs PCP, which are provided on the substrate 10, peripheral circuit lines PLP, which are electrically connected to the peripheral transistors PTR through the peripheral plugs PCP, first bonding pads BP1, which are electrically connected to the peripheral circuit lines PLP, and a lower insulating layer covering them.

The peripheral transistors PTR may be provided on active regions of the substrate 10. The peripheral transistors PTR may be row and column decoders, a page buffer, and a control circuit. In some implementations, the peripheral transistors PTR may include NMOS and PMOS transistors.

The peripheral plugs PCP and the peripheral transistors PTR may be electrically connected to each other. For example, the peripheral plugs PCP may be connected to source and drain regions of each of the peripheral transistors PTR. The peripheral circuit lines PLP may be electrically connected to the peripheral transistors PTR through the peripheral plugs PCP. For example, the peripheral plugs PCP and the peripheral circuit lines PLP may be formed of or include at least one of metallic materials (e.g., Ti, Mo, W, Cu, Al, Au, Ta, Ru, and Ir) or metal nitride materials (e.g., nitride materials containing Ti, Mo, W, Cu, Al, Ta, Ru, and Ir).

A lower insulating layer may be placed on the substrate 10. The lower insulating layer may include a first lower insulating layer 11 and a second lower insulating layer 13 on the first lower insulating layer 11. The first lower insulating layer 11 may cover the peripheral transistors PTR, the peripheral plugs PCP, the peripheral circuit lines PLP. The second lower insulating layer 13 may be provided to cover a top surface of the first lower insulating layer 11 and side surfaces of the first bonding pads BP1 and to expose top surfaces of the first bonding pads BP1. In some implementations, a top surface of the second lower insulating layer 13 may be coplanar with the top surfaces of the first bonding pads BP1. The peripheral circuit structure PS may further include an etch stop layer between the first lower insulating layer 11 and the second lower insulating layer 13.

The cell array structure CS may be placed on the peripheral circuit structure PS. The cell array structure CS may include first to third interlayer insulating layers 110, 120, and 130, a stack ST, a mold structure MS, the vertical structures VS, first gate contacts GMC1, second gate contacts GMC2, and input/output contacts IOMC. In some implementations, various elements, which are used to electrically connect the cell array structure CS to the peripheral circuit structure PS, may be provided in the first to third interlayer insulating layers 110, 120, and 130.

The third interlayer insulating layer 130 may be placed on the second lower insulating layer 13 of the peripheral circuit structure PS to cover the second lower insulating layer 13. Second bonding pads BP2 may be provided in the third interlayer insulating layer 130. The second bonding pads BP2 may be in contact with the first bonding pads BP1, respectively, and may form a hybrid bonding structure. In the present disclosure, the hybrid bonding structure may mean a bonding structure, which is formed by fusing two elements, which contain the same kind of material, into a single element at an interface therebetween. Accordingly, the first and second bonding pads BP1 and BP2 may be bonded to form a single object.

A second interlayer insulating layer 120 may be placed on the third interlayer insulating layer 130. Upper conductive lines UCL, lower conductive lines LCL, and the bit lines BL may be provided in the second interlayer insulating layer 120. The lower conductive lines LCL and the bit lines BL may be placed on the upper conductive lines UCL. For example, the upper conductive lines UCL may be placed in a lower portion of the second interlayer insulating layer 120, and the lower conductive lines LCL and the bit lines BL may be placed in an upper portion of the second interlayer insulating layer 120. In addition, the bit lines BL may be placed on the cell array region CAR, and the lower conductive lines LCL may be placed on the connection region CCR. Each of the upper conductive lines UCL may electrically connect a corresponding one of the lower conductive lines LCL or the bit lines BL to the second bonding pads BP2.

In some implementations, the cell array structure CS may further include an etch stop layer placed between the third interlayer insulating layer 130 and the second interlayer insulating layer 120.

A first interlayer insulating layer 110 may be placed on the second interlayer insulating layer 120. Bit line plugs BLCP and conductive line plugs CLCP may be provided in the first interlayer insulating layer 110. The bit line plugs BLCP may be placed between the vertical structures VS and the bit lines BL to electrically connect them to each other. The conductive line plugs CLCP may be placed between the first and second gate contacts GMC1 and GMC2 and the lower conductive lines LCL or between the input/output contacts IOMC to electrically connect them to each other. For example, the bit line plugs BLCP may be placed on the cell array region CAR, and the conductive line plugs CLCP may be placed on the connection region CCR.

The stack ST, which includes a first block BK1 and a second block BK2, and the mold structure MS, which includes a third block BK3, may be placed on the first interlayer insulating layer 110. Each of the first and second blocks BK1 and BK2 of the stack ST may be extended in the first direction D1 and may be spaced apart from each other in the second direction D2. The third block BK3 of the mold structure MS may be placed at a side of the second block BK2. The third block BK3 may be spaced apart from the first block BK1, in the second direction D2, with the second block BK2 interposed therebetween.

In some implementations, the first block BK1 may be a memory cell block that is configured to store data. The second block BK2 may be a dummy block that is not configured to store data. The third block BK3 may be a block, in which the input/output contacts IOMC connecting the semiconductor memory device to an external device is provided.

In some implementations, a plurality of first blocks BK1, a plurality of second blocks BK2, and a plurality of third blocks BK3 may be provided. In this case, the first blocks BK1 may be placed to be adjacent to each other. The second block BK2 and the third block BK3 may be sequentially provided at both sides of the first blocks BK1.

When viewed in a plan view, separation structures SS, which are extended in the first direction D1, may be provided at both sides of the first block BK1. One of the separation structures SS may be provided to cross a region between the first block BK1 and the second block BK2. The separation structures SS may be provided to penetrate the stack ST and to electrically separate the first and second blocks BK1 and BK2 from each other.

The stack ST may include gate electrodes GE and insulating layers ILD, which are alternately stacked in the third direction D3. The mold structure MS may include sacrificial layers SL and the insulating layers ILD, which are alternately stacked in the third direction D3. In some implementations, the gate electrodes GE and the sacrificial layers SL may have substantially the same thickness. The gate electrodes GE and the sacrificial layers SL, which correspond to each other, may be placed at the same level. In the present disclosure, the term “level” may mean a height measured from the top surface of the substrate 10 in the third direction D3. The lowermost one of the insulating layers ILD may be thicker than the remaining ones of the insulating layers ILD, but the inventive concept is not limited to this example.

The stack ST may have a first surface STa and a second surface STb, which are opposite to each other, and the mold structure MS may have a third surface MSa and a fourth surface MSb, which are opposite to each other. The first surface STa of the stack ST and the third surface MSa of the mold structure MS may face the peripheral circuit structure PS. The first surface STa of the stack ST may be substantially coplanar with the third surface MSa of the mold structure MS, and the second surface STb of the stack ST may be substantially coplanar with the fourth surface MSb of the mold structure MS. In addition, each of the stack ST and the mold structure MS may have a length in the third direction D3. A vertical length STL of the stack ST in the third direction D3 may be substantially equal to a vertical length MSL of the mold structure MS in the third direction D3.

In some implementations, the gate electrodes GE may be formed of or include at least one of doped semiconductor materials (e.g., doped silicon), metallic materials (e.g., tungsten, copper, and aluminum), conductive metal nitrides (e.g., titanium nitride and tantalum nitride), or transition metals (e.g., titanium and tantalum). The insulating layers ILD may be formed of or include at least one of silicon oxide and/or low-k dielectric materials. The sacrificial layers SL may be formed of or include silicon nitride.

The gate electrodes GE, the sacrificial layers SL, and the insulating layers ILD may be extended in the first direction D1 and may have lengths in the first direction D1. The lengths of the gate electrodes GE, the sacrificial layers SL, and the insulating layers ILD in the first direction D1 may be substantially equal to each other. That is, the gate electrodes GE, the sacrificial layers SL, and the insulating layers ILD may have substantially the same horizontal length. That is, the stack ST and the mold structure MS may not have a staircase structure on the connection region CCR. Accordingly, the stack ST and the mold structure MS in the connection region CCR may have reduced lengths in the first direction D1. Thus, the size of the three-dimensional semiconductor memory device may be reduced.

In some implementations, the three-dimensional semiconductor memory device may be a vertical-type NAND FLASH memory device. In this case, the gate electrodes GE of the stack ST may be used as the gate electrodes of the string selection transistor, the memory cell transistors, and the ground selection transistors of FIG. 1.

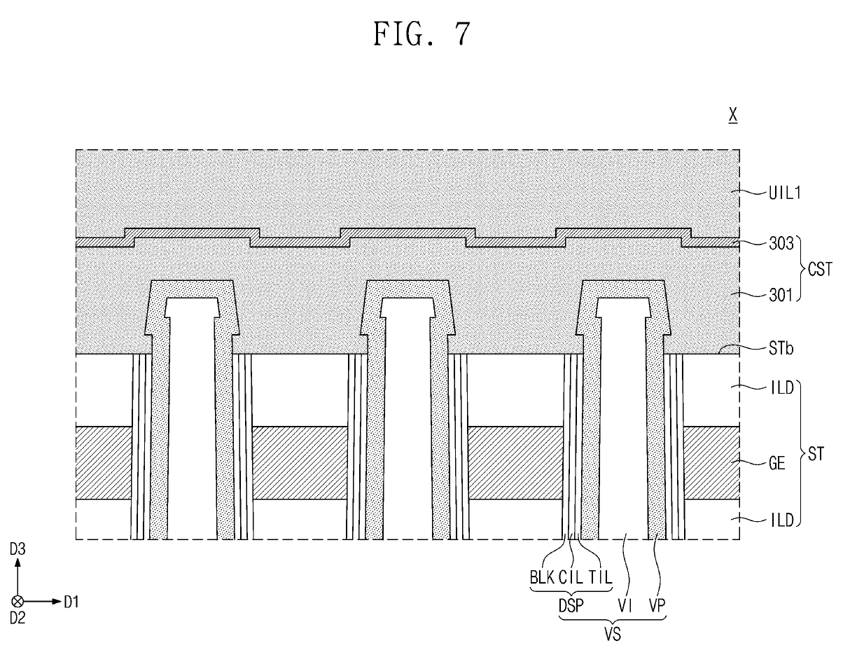

The vertical structures VS may be disposed on the cell array region CAR. When viewed in a plan view, the vertical structures VS may be arranged in a specific direction or in a zigzag shape. The vertical structures VS may be provided to penetrate the first and second blocks BK1 and BK2 of the stack ST. Each of the vertical structures VS may be extended in the third direction D3 and may be connected to a source structure CST to be described below. Each of the vertical structures VS may be provided to penetrate a portion of the source structure CST and may be further extended into the source structure CST. The vertical structures VS may be electrically connected to the bit lines BL through the bit line plugs BLCP. Each of the vertical structures VS may be provided to have a multi-layered structure, and the vertical structures VS will be described in more detail with reference to FIG. 7.

The first and second gate contacts GMC1 and GMC2 may be provided on the connection region CCR. When viewed in a plan view, the first and second gate contacts GMC1 and GMC2 may be spaced apart from each other in the first and second directions D1 and D2, in the connection region CCR. The first gate contacts GMC1 may be provided to penetrate a portion of the first block BK1 of the stack ST, and the second gate contacts GMC2 may be provided to penetrate the second block BK2 of the stack ST. For example, the first and second gate contacts GMC1 and GMC2 may be formed of or include at least one of metallic materials (e.g., tungsten, copper, and aluminum), conductive metal nitrides (e.g., titanium nitride and tantalum nitride), or transition metals (e.g., titanium and tantalum).

Each of the first gate contacts GMC1 may be connected to one of the gate electrodes GE of the stack ST. Since the gate electrodes GE of the stack ST are placed at different levels in the third direction D3, the first gate contacts GMC1 may have different lengths from each other in the third direction D3. For example, each of the first gate contacts GMC1 may have a first length L1 in the third direction D3, and the first lengths L1 of the first gate contacts GMC1 may be different from each other. The largest of the first lengths L1 of the first gate contacts GMC1 may be smaller than the vertical length STL of the stack ST.

In other words, the first gate contacts GMC1 may have top surfaces, which are placed at different levels, and bottom surfaces, which are placed at the same level. The bottom surfaces of the first gate contacts GMC1 may be coplanar with the first surface STa of the stack ST. That is, the first gate contacts GMC1 may be aligned along the first surface STa of the stack ST. In addition, the first gate contacts GMC1 may be electrically connected to the lower conductive lines LCL through corresponding ones of the conductive line plugs CLCP. Accordingly, the first gate contacts GMC1 may electrically connect the peripheral transistors PTR of the peripheral circuit structure PS to the gate electrodes GE of the stack ST.

First gate insulating patterns GCIP1 may be further provided between the first gate contacts GMC1 and the first block BK1 of the stack ST. The first gate insulating patterns GCIP1 may be extended in the third direction D3 and along the side surfaces of corresponding ones of the first gate contacts GMC1. When viewed in a plan view, the first gate insulating patterns GCIP1 may be provided to enclose the corresponding first gate contacts GMC1. For example, the first gate insulating patterns GCIP1 may be formed of or include at least one of insulating materials (e.g., silicon oxide and/or low-k dielectric materials). Accordingly, the first gate contacts GMC1 may be electrically disconnected from the gate electrodes GE that are not connected thereto.

The second gate contacts GMC2 may not be connected to the gate electrodes GE of the stack ST. Each of the second gate contacts GMC2 may be provided to fully penetrate the second block BK2 of the stack ST. The second gate contacts GMC2 may be further extended into first device isolation patterns STI1, respectively, which are formed in a first upper insulating layer UIL to be described below. In this case, a second length L2 of each of the second gate contacts GMC2 in the third direction D3 may be larger than the vertical length STL of the stack ST.

In other words, the second gate contacts GMC2 may have bottom surfaces, which are placed at the same level, and top surfaces, which are placed at the same level. The bottom surfaces of the second gate contacts GMC2 may be placed at the same level as the bottom surfaces of the first gate contacts GMC1 and the first surface STa of the stack ST. Similar to the first gate contacts GMC1, the second gate contacts GMC2 may be aligned along the first surface STa of the stack ST and may be electrically connected to the lower conductive lines LCL through the corresponding conductive line plugs CLCP. Accordingly, the second gate contacts GMC2 may electrically connect the peripheral transistors PTR of the peripheral circuit structure PS to input/output pads PAD to be described below.

Second gate insulating patterns GCIP2 may be further provided between the second gate contacts GMC2 and the second block BK2 of the stack ST. The second gate insulating patterns GCIP2 may be extended in the third direction D3 and along the side surfaces of corresponding ones of the second gate contacts GMC2. When viewed in a plan view, the second gate insulating patterns GCIP2 may be provided to enclose the corresponding second gate contacts GMC2. The second gate insulating patterns GCIP2 may include substantially the same insulating material as the first gate insulating patterns GCIP1. Accordingly, the second gate contacts GMC2 may be electrically disconnected from the gate electrodes GE.

Dummy vertical structures DVS may be further provided in the connection region CCR. When viewed in a plan view, the first and second gate contacts GMC1 and GMC2 may be disposed to be adjacent to the dummy vertical structures DVS. For example, each of the first and second gate contacts GMC1 and GMC2 may be placed between adjacent ones of the dummy vertical structures DVS. Similar to the vertical structures VS, the dummy vertical structures DVS may be provided to penetrate the first and second blocks BK1 and BK2 of the stack ST. Unlike the vertical structures VS, the dummy vertical structures DVS may be composed of a single layer, but the present disclosure is not limited to this example.

The input/output contacts IOMC may be disposed on the cell array region CAR and the connection region CCR. When viewed in a plan view, the input/output contacts IOMC may be two-dimensionally arranged. For example, the input/output contacts IOMC may be spaced apart from each other in the first and second directions D1 and D2. The input/output contacts IOMC may be provided to penetrate the third block BK3 of the mold structure MS. The input/output contacts IOMC may be extended in the third direction D3 and may be inserted into second device isolation patterns STI2, respectively, which are provided on the mold structure MS. Accordingly, a third length L3 of each of the input/output contacts IOMC in the third direction D3 may be larger than the vertical length MSL of the mold structure MS. The third length L3 of each of the input/output contacts IOMC may be substantially equal to or larger than the second length L2 of each of the second gate contacts GMC2. For example, the input/output contacts IOMC may be formed of or include at least one of metallic materials (e.g., Ti, Mo, W, Cu, Al, Au, Ta, Ru, and Ir) or metal nitride materials (e.g., containing Ti, Mo, W, Cu, Al, Ta, Ru, and Ir).

The input/output contacts IOMC may have bottom surfaces, which are placed at the same level, and top surfaces, which are placed at the same level. The bottom surfaces of the input/output contacts IOMC may be placed at the same level as the third surface MSa of the mold structure MS. That is, the input/output contacts IOMC may be aligned along the third surface MSa of the mold structure MS. Since the third surface MSa of the mold structure MS is coplanar with the first surface STa of the stack ST, the input/output contacts IOMC and the first and second gate contacts GMC1 and GMC2 may be aligned along the first surface STa of the stack ST and the third surface MSa of the mold structure MS. In addition, the input/output contacts IOMC may be electrically connected to the lower conductive lines LCL through the corresponding conductive line plugs CLCP. Accordingly, the input/output contacts IOMC may electrically connect the peripheral transistors PTR of the peripheral circuit structure PS to the input/output pads PAD.

Input/output insulating patterns IOIP may be further provided between the input/output contacts IOMC and the third block BK3 of the mold structure MS. The input/output insulating patterns IOIP may be extended in the third direction D3 to cover side surfaces of the corresponding input/output contacts IOMC. When viewed in a plan view, the input/output insulating patterns IOIP may be provided to enclose the corresponding input/output contacts IOMC. The input/output insulating patterns IOIP may include substantially the same insulating material as the first and second gate insulating patterns GCIP1 and GCIP2.

The source structure CST may be provided on the cell array region CAR and on the stack ST. The source structure CST may correspond to the common source line 3205 or 4205 of FIGS. 3 or 4. The source structure CST may be extended in the first and second directions D1 and D2. The source structure CST may cover portions of the vertical structures VS protruding from the second surface STb of the stack ST. The source structure CST may include a first source conductive pattern 301 and a second source conductive pattern 303. The first source conductive pattern 301 may cover the second surface STb of the stack ST. The second source conductive pattern 303 may be placed on the first source conductive pattern 301 to cover the first source conductive pattern 301. The second source conductive pattern 303 may be spaced apart from the vertical structures VS in the third direction D3. For example, the first source conductive pattern 301 may be formed of or include at least one of semiconductor materials doped with n- or p-type impurities. The second source conductive pattern 303 may be formed of or include at least one of metallic materials (e.g., Ti, Mo, W, Cu, Al, Au, Ta, Ru, and Ir) or metallic nitride materials (e.g., containing Ti, Mo, W, Cu, Al, Au, Ta, Ru, and Ir).

A first upper insulating layer UIL1 may be provided on the stack ST and the mold structure MS. In the cell array region CAR, the first upper insulating layer UIL1 may cover the source structure CST. In the connection region CCR, the first upper insulating layer UIL1 may cover the stack ST and the mold structure MS. The first upper insulating layer UIL1 may include at least one of, for example, HDP or TEOS.

The first and second device isolation patterns STI1 and STI2 may be provided in the first upper insulating layer UIL1. The first device isolation patterns STI1 may be placed on the second block BK2 of the stack ST, in the connection region CCR, and may be vertically overlapped with the second gate contacts GMC2, respectively. The second gate contacts GMC2 may be provided to penetrate a portion of each of the corresponding first device isolation patterns STI1. The second device isolation patterns STI2 may be placed on the third block BK3 of the mold structure MS and may be vertically overlapped with the input/output contacts IOMC, respectively. The input/output contacts IOMC may be provided to penetrate a portion of each of the corresponding second device isolation patterns STI2. The first device isolation patterns STI1 may be in contact with the second surface STb of the stack ST, and the second device isolation patterns STI2 may be in contact with the fourth surface MSb of the mold structure MS. The first upper insulating layer UIL1 may cover the first and second device isolation patterns STI1 and STI2.

As described below, the first device isolation patterns STI1 may prevent portions of the second gate contacts GMC2, which protrude from the second surface STb of the stack ST, from being exposed to the outside. The second device isolation patterns STI2 may prevent portions of the input/output contacts IOMC, which protrude from the fourth surface MSb of the mold structure MS, from being exposed to the outside. Accordingly, it may be possible to prevent the second gate contacts GMC2 and the input/output contacts IOMC from being damaged. Accordingly, the electrical and durability characteristics of the three-dimensional semiconductor memory device may be improved.

Via patterns VA may be provided in the first upper insulating layer UIL1. The via patterns VA may be placed on the second block BK2 of the stack ST and the third block BK3 of the mold structure MS. Some of the via patterns VA may be provided to penetrate the first device isolation patterns STI1 and may be connected to the corresponding second gate contacts GMC2. The remaining ones of the via patterns VA may be provided to penetrate the second device isolation patterns STI2 and may be connected to the input/output contacts IOMC. Top surfaces of the via patterns VA may be placed at substantially the same level as a top surface of the first upper insulating layer UIL1 and may be coplanar with each other. The via patterns VA may be formed of or include at least one of metallic materials (e.g., Ti, Mo, W, Cu, Al, Au, Ta, Ru, and Ir) or metal nitride materials (e.g., nitride materials containing Ti, Mo, W, Cu, Al, Ta, Ru, and Ir).

A second upper insulating layer UIL2 may be placed on the first upper insulating layer UIL1. The second upper insulating layer UIL2 may cover the first upper insulating layer UIL1 and the input/output pads PAD. A top surface of the second upper insulating layer UIL2 may have an uneven structure, but the present disclosure is not limited to this example. The second upper insulating layer UIL2 may be formed of or include at least one of SiN, HDP, or TEOS.

The input/output pads PAD may be provided in the second upper insulating layer UIL2. The input/output pads PAD may correspond to the input/output pad 1101 of FIG. 1 and the input/output pad 2210 of FIGS. 3 or 4. The input/output pads PAD may be connected to the corresponding via patterns VA. The input/output pads PAD may be electrically connected to the second gate contacts GMC2 or the input/output contacts IOMC through the via patterns VA. Top surfaces of the input/output pads PAD may be exposed through openings OP to be described below. In some implementations, each of the input/output pads PAD may be formed of or include at least one of metallic materials (e.g., Ti, Mo, W, Cu, Al, Au, Ta, Ru, and Ir).

A protection layer PTL may be provided on the second upper insulating layer UIL2. The protection layer PTL may cover the top surface of the second upper insulating layer UIL2. Top and bottom surfaces of the protection layer PTL may have an uneven structure, but the present disclosure is not limited to this example. For example, the protection layer PTL may be formed of or include at least one of metal oxide materials (e.g., aluminum oxide, zirconium oxide, hafnium oxide, tantalum oxide, and hafnium aluminum oxide) or high-k dielectric materials.

A passivation layer PAS may be provided on the protection layer PTL. The passivation layer PAS may cover the top surface of the protection layer PTL. For example, the passivation layer PAS may include at least one of polyimide-based materials (e.g., photo sensitive polyimide (PSPI)).

The openings OP may be provided to penetrate the second upper insulating layer UIL2, the protection layer PTL, and the passivation layer PAS and to expose the input/output pads PAD. The openings OP may be vertically overlapped with the corresponding input/output pads PAD. Side surfaces of the second upper insulating layer UIL2, the protection layer PTL, and the passivation layer PAS may be exposed through the openings OP.

In some implementations, the three-dimensional semiconductor memory device may include the first gate contacts GMC1 in the first block BK1 of the stack ST and the second gate contacts GMC2 in the second block BK2 of the stack ST. The first gate contacts GMC1 may be connected to the gate electrodes GE and may be used to apply voltages to the gate electrodes GE. The second gate contacts GMC2 may be provided to electrically connect the input/output pads PAD to the peripheral transistors PTR of the peripheral circuit structure PS.

In other words, the three-dimensional semiconductor memory device may be configured in such a way that the gate contacts in the dummy block execute substantially the same function as the input/output contacts. Accordingly, electrical signals and voltages may be easily transmitted to the three-dimensional semiconductor memory device. Accordingly, the electrical characteristics of the three-dimensional semiconductor memory device may be improved.

In some implementations, the first gate insulating patterns GCIP1, the second gate insulating patterns GCIP2, and the input/output insulating patterns IOIP may be formed at the same time. The first gate contacts GMC1, the second gate contacts GMC2, and the input/output contacts IOMC may be formed at the same time. Accordingly, a process of fabricating a three-dimensional semiconductor memory device may be simplified.

FIG. 7 is an enlarged sectional view illustrating an example of a portion (e.g., X of FIG. 6A) of a three-dimensional semiconductor memory device according to some implementations. In FIG. 7, each of the vertical structures may include a vertical semiconductor pattern VP, a data storage pattern DSP enclosing an inner side surface of the vertical semiconductor pattern VP, and a gapfill insulating pattern VI filling an inner space of the vertical semiconductor pattern VP.

The vertical semiconductor pattern VP may have a shape that is extended from the stack ST to the first source conductive pattern 301 of the source structure CST. For example, an upper end of the vertical semiconductor pattern VP may have a shape protruding from the second surface STb of the stack ST. The upper end of the vertical semiconductor pattern VP may have a pipe or macaroni shape with a closed top. In some implementations, the upper end of the vertical semiconductor pattern VP may have an inverted ‘U’ shape, when viewed in a sectional view, but the inventive concept is not limited to this example. For example, the vertical semiconductor pattern VP may include at least one of doped semiconductor materials, undoped or intrinsic semiconductor materials, and polycrystalline semiconductor materials.

The data storage pattern DSP may be placed between the vertical semiconductor pattern VP and the stack ST. The data storage pattern DSP may not be extended into the first source conductive pattern 301 of the source structure CST. For example, a top surface of the data storage pattern DSP may be substantially coplanar with the second surface STb of the stack ST. The data storage pattern DSP may have a pipe or macaroni shape with an open top. Accordingly, the data storage pattern DSP may not be in contact with the upper end of the vertical semiconductor pattern VP.

The data storage pattern DSP may include a tunnel insulating layer TIL, a charge storing layer CIL, and a blocking insulating layer BLK, which are sequentially stacked on a side surface of the vertical semiconductor pattern VP. The tunnel insulating layer TIL may be in contact with the side surface of the vertical semiconductor pattern VP. The blocking insulating layer BLK may be in contact with the stack ST. The charge storing layer CIL may be placed between the tunnel insulating layer TIL and the blocking insulating layer BLK. Each of the tunnel insulating layer TIL, the charge storing layer CIL, and the blocking insulating layer BLK may be extended in a vertical direction, between the vertical semiconductor pattern VP and the stack ST. In some implementations, the Fowler-Nordheim tunneling phenomenon, which is caused by a voltage difference between the vertical semiconductor pattern VP and the gate electrodes GE of the stack ST, may be used to store and change data in the data storage pattern DSP. For example, each of the blocking and tunnel insulating layers BLK and TIL may include silicon oxide, and the charge storing layer CIL may include at least one of silicon nitride or silicon oxynitride.

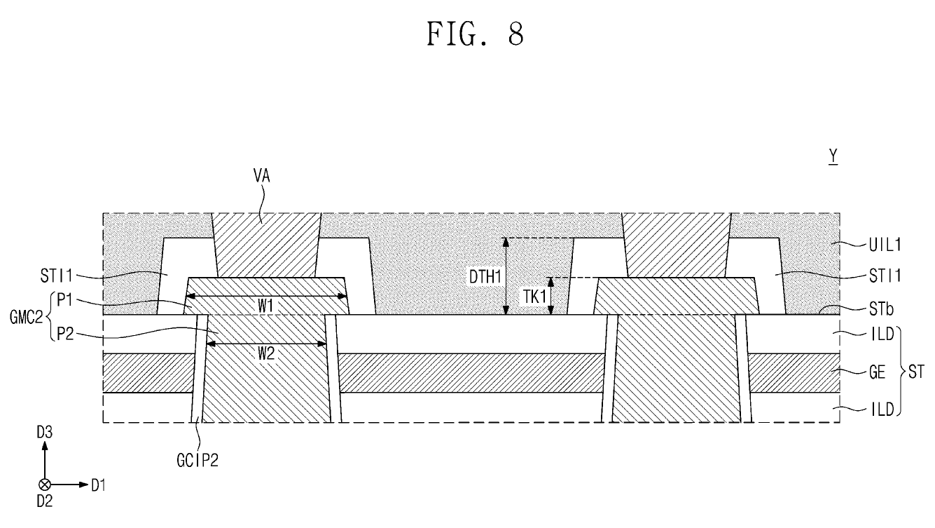

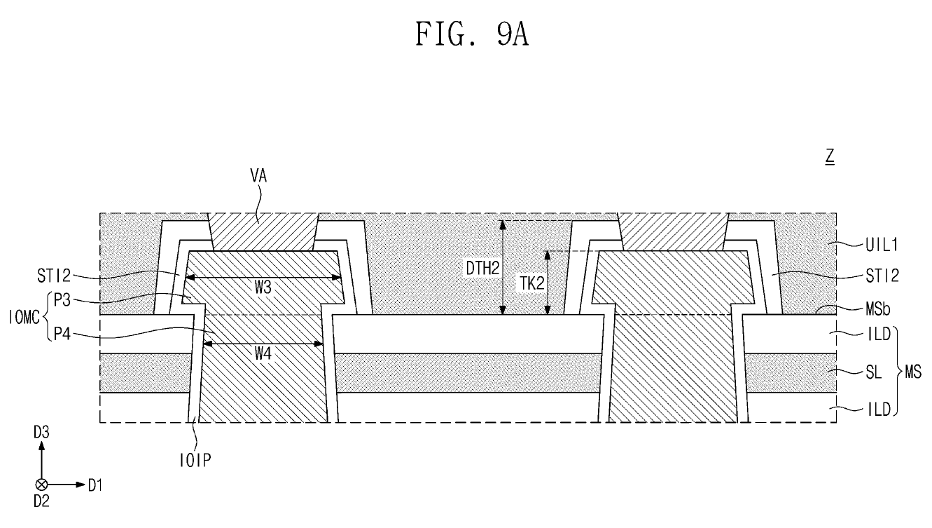

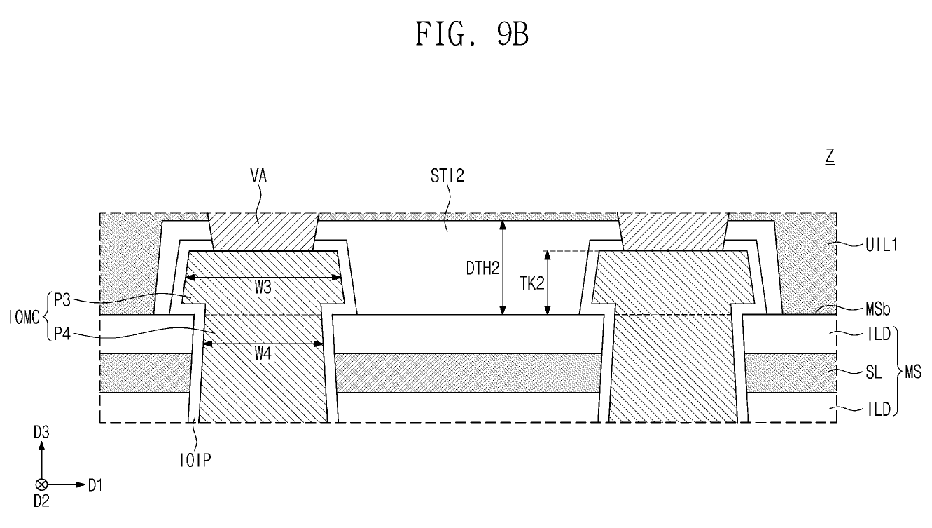

FIG. 8 is an enlarged sectional view illustrating an example of a portion (e.g., Y of FIG. 6B) of a three-dimensional semiconductor memory device according to some implementations. FIGS. 9A and 9B are enlarged sectional views illustrating an example of a portion (e.g., Z of FIG. 6B) of a three-dimensional semiconductor memory device according to some implementations.

In FIG. 8, each of the second gate contacts GMC2 may include a first portion P1 and a second portion P2 below the first portion P1. The first portion P1 may be placed in the first device isolation patterns STI1. The second portion P2 may be placed in the stack ST and may be extended in a vertical direction. For example, the first and second portions P1 and P2 may be defined, based on the second surface STb of the stack ST.

The first portion P1 may have a first width W1 in a horizontal direction and may have a first thickness TK1 in a vertical direction. The first width W1 may be a mean width of the first portion P1 in a horizontal direction. The second portion P2 may have a second width W2 at its top level. For example, the second width W2 may be a width of the second portion P2 adjacent to the first portion P1. The first width W1 may be larger than the second width W2. Accordingly, a stepwise structure may be formed between the first and second portions P1 and P2.

The second gate insulating patterns GCIP2 may be placed between the second portion P2 and the stack ST and may be aligned along the second surface STb of the stack ST. The second gate insulating patterns GCIP2 may be absent between the first portion P1 and the first device isolation patterns STI1. In other words, the second gate insulating patterns GCIP2 may not be extended from a region between the second gate contacts GMC2 and the stack ST to a region between the second gate contacts GMC2 and the first device isolation patterns STI1.

Each of the first device isolation patterns STI1 may have a first depth DTH1 in a vertical direction. The first depth DTH1 may be a thickness of each of the first device isolation patterns STI1. The first depth DTH1 of each of the first device isolation patterns STI1 may be larger than the first thickness TK1 of the first portion P1. Accordingly, top surfaces of the first device isolation patterns STI1 may be placed at a level higher than a top surface of the first portion P1. Accordingly, due to the first device isolation patterns STI1, the first portion P1 may not be exposed to the outside and may be protected by the first device isolation pattern STI1.

In some implementations, the first and second portions P1 and P2 may include substantially the same material. In this case, even when the first and second portions P1 and P2 are formed through different processes, there may be no visible interface between the first and second portions P1 and P2. For example, the first and second portions P1 and P2 may be provided to form a single object.

In FIGS. 9A and 9B, each of the input/output contacts IOMC may include a third portion P3 and a fourth portion P4 below the third portion P3. The third portion P3 may be placed in the second device isolation patterns STI2. The fourth portion P4 may be placed in the mold structure MS and may be extended in a vertical direction. The third and fourth portions P3 and P4 may be defined, based on the fourth surface MSb of the mold structure MS. The third portion P3 may have a rectangular shape, in a sectional view, but the inventive concept is not limited to this example. For example, the third portion P3 may have a circular, elliptical, or polygonal shape, when viewed in a sectional view.

The third portion P3 may have a third width W3 in a horizontal direction and may have a second thickness TK2 in a vertical direction. The third width W3 may be a mean width of the third portion P3 in a horizontal direction. The fourth portion P4 may have a fourth width W4 at its top level. The fourth width W4 may be a width of the fourth portion P4 adjacent to the third portion P3. The third width W3 may be larger than the fourth width W4. The second thickness TK2 of the third portion P3 may be larger than the first thickness TK1 of the first portion P1. Thus, the second length (e.g., L2 of FIG. 6A) of each of the second gate contacts GMC2 may be smaller than the third length (e.g., L3 of FIG. 6A) of each of the input/output contacts IOMC.

The input/output insulating patterns IOIP may be extended from a region between the input/output contacts IOMC and the mold structure MS to a region between the input/output contacts IOMC and the second device isolation patterns STI2. For example, the input/output insulating patterns IOIP may cover surfaces of the third and fourth portions P3 and P4. In the case where the input/output insulating patterns IOIP include substantially the same material as the second device isolation patterns STI2, there may be no visible interface between the input/output insulating patterns IOIP and the second device isolation patterns STI2.

Each of the second device isolation patterns STI2 may have a second depth DTH2 in a vertical direction. The second depth DTH2 may be a thickness of each of the second device isolation patterns STI2. The second depth DTH2 of each of the second device isolation patterns STI2 may be larger than the second thickness TK2 of the third portion P3. In this case, top surfaces of the second device isolation patterns STI2 may be located at a level higher than a top surface of the third portion P3. Due to the second device isolation patterns STI2, the third portion P3 may not be exposed to the outside. In addition, the second depth DTH2 of each of the second device isolation patterns STI2 may be larger than the first depth DTH1 of each of the first device isolation patterns STI1, but the present disclosure is not limited to this example.

In some implementations, adjacent ones of the second device isolation patterns STI2 may be connected to each other. The second device isolation patterns STI2, which are connected to each other, may constitute a single second device isolation pattern STI2. In this case, the input/output contacts IOMC, which are adjacent to each other, may be provided to partially penetrate one of the second device isolation patterns STI2. That is, a plurality of input/output contacts IOMC may share one of the second device isolation patterns STI2.

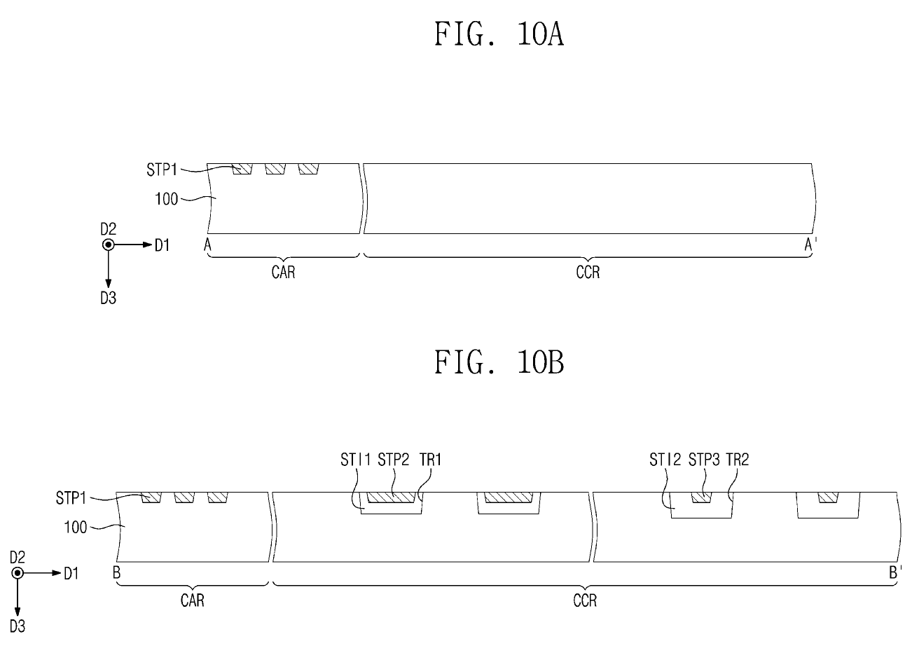

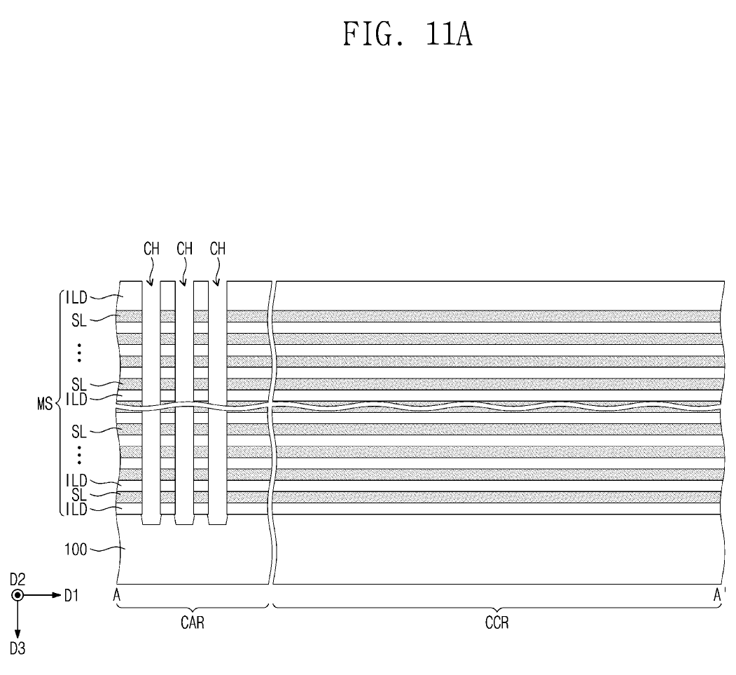

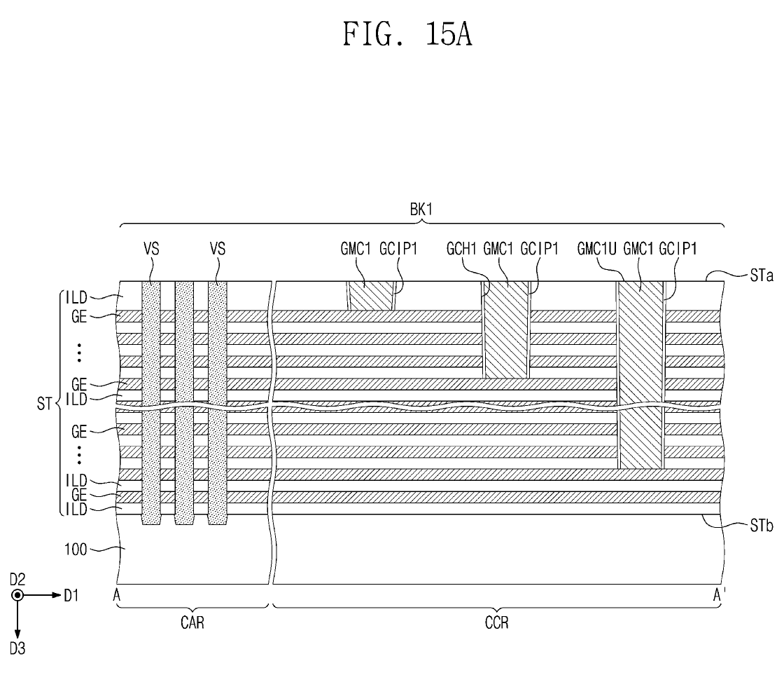

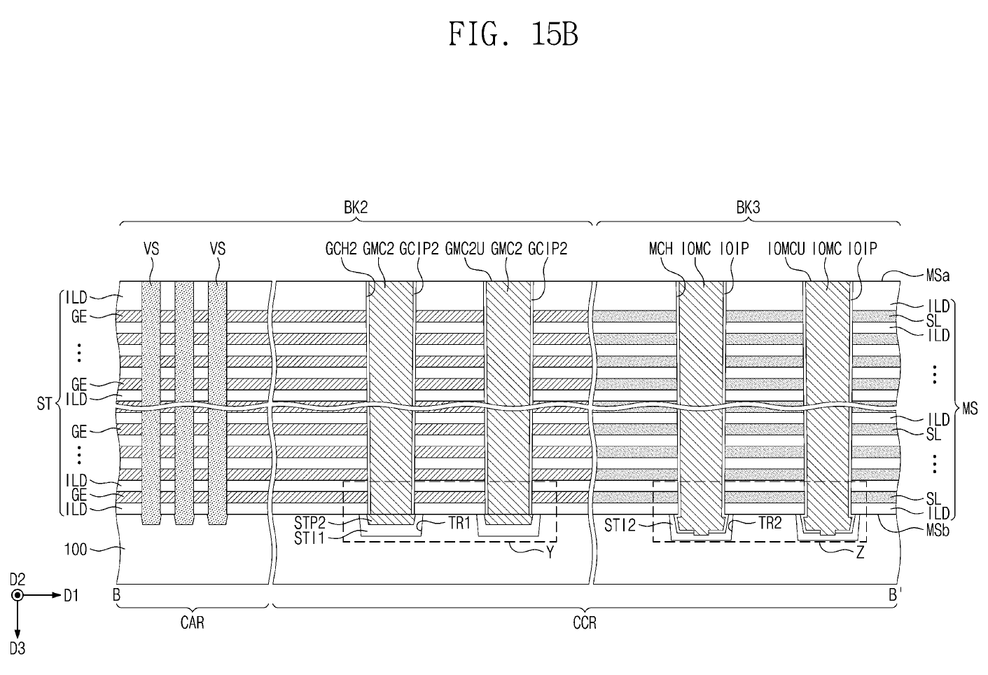

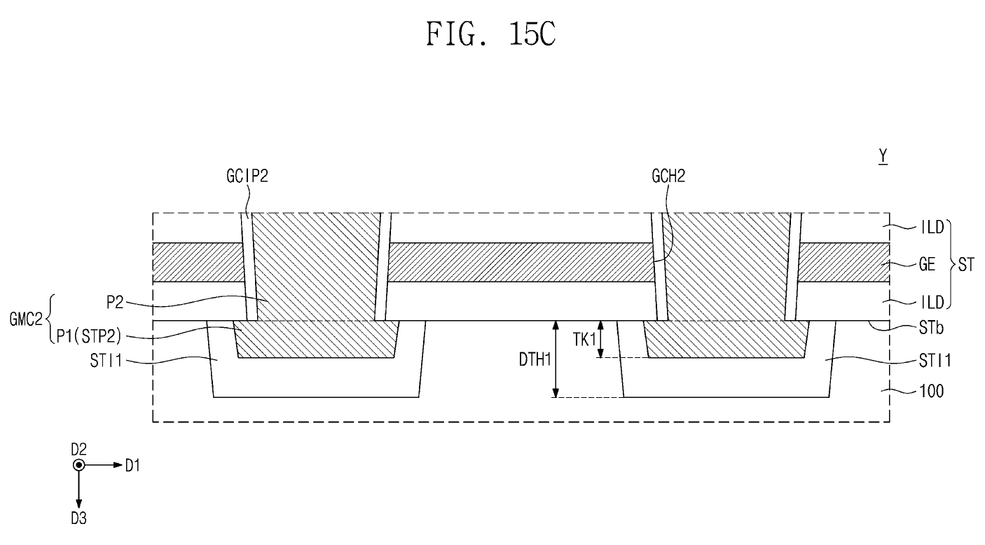

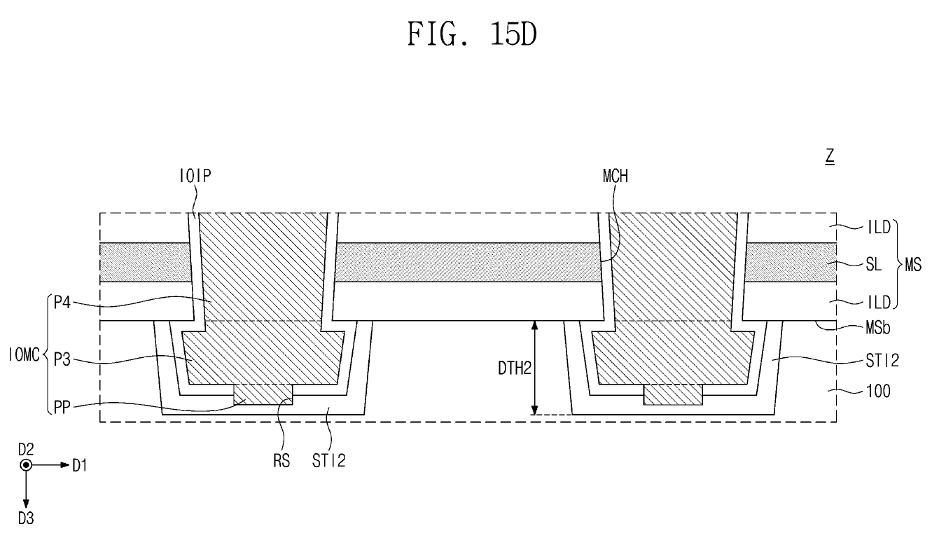

FIGS. 10A to 16B are sectional views illustrating an example of a method of fabricating a three-dimensional semiconductor memory device according to some implementations. FIGS. 10A, 11A, 12A, 13A, 14A, 15A, and FIG. 16A are sectional views taken along the line A-A’ of FIG. 5, FIGS. 10B, 11B, 12B, 13B, 14B, 15B, and FIG. 16B are sectional views taken along the line B-B’ of FIG. 5, and FIGS. 15C and 15D are sectional views illustrating portions Y and X of FIG. 15B.

In FIGS. 10A and 10B, a carrier substrate 100 including the cell array region CAR and the connection region CCR may be provided. The carrier substrate 100 may be one of a silicon substrate, a silicon-germanium substrate, a germanium substrate, and a structure including a single-crystalline silicon substrate and a single-crystalline epitaxial layer grown therefrom, but the inventive concept is not limited to this example.

First stop patterns STP1 may be formed in the cell array region CAR of the carrier substrate 100. The first stop patterns STP1 may be formed in empty regions, which are formed by patterning an upper portion of the carrier substrate 100. The first stop patterns STP1 may be formed of or include at least one of metallic materials (e.g., W, Cu, Al, and Ti).

The first and second device isolation patterns STI1 and STI2 may be formed in the connection region CCR of the carrier substrate 100. The formation of the first and second device isolation patterns STI1 and STI2 may include recessing an upper portion of the carrier substrate 100 to form first and second trenches TR1 and TR2, filling the first and second trenches TR1 and TR2 with an insulating material, and performing a planarization process on the insulating material. A vertical depth of each of the first trenches TR1 may be smaller than a vertical depth of each of the second trenches TR2, but the inventive concept is not limited to this example.

Second stop patterns STP2 may be formed in the first device isolation patterns STI1, and third stop patterns STP3 may be formed in the second device isolation patterns STI2. For example, the second and third stop patterns STP2 and STP3 may be formed of or include at least one of metallic materials (e.g., W, Cu, Al, and Ti).

In some implementations, the second and third stop patterns STP2 and STP3 may be formed simultaneously with the first stop patterns STP1. A horizontal width of each of the second stop patterns STP2 may be larger than a horizontal width of each of the first stop patterns STP1. A horizontal width of each of the third stop patterns STP3 may be substantially equal to the horizontal width of each of the first stop patterns STP1.

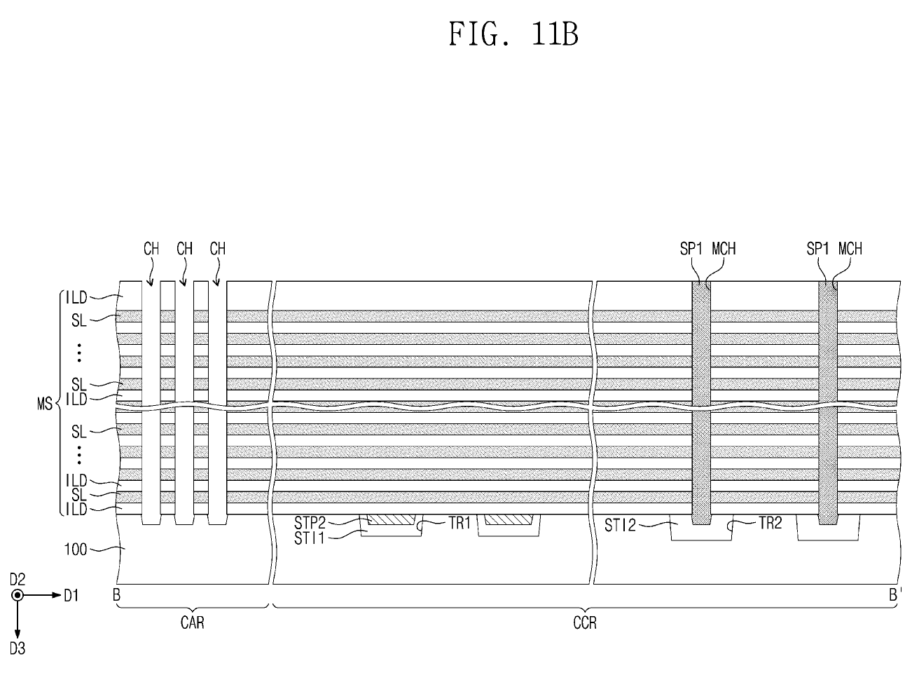

In FIGS. 11A and 11B, the mold structure MS may be formed on the carrier substrate 100. The formation of the mold structure MS may include alternately forming the insulating layers ILD and the sacrificial layers SL in the third direction D3. The insulating layers ILD and the sacrificial layers SL may be formed by a chemical vapor deposition (CVD) process or an atomic layer deposition (ALD) process. The sacrificial layers SL and the insulating layers ILD may have an etch selectivity with respect to each other. Accordingly, the insulating layers ILD may not be removed, even when the sacrificial layers SL are removed. For example, the sacrificial layers SL may include silicon nitride, and the insulating layers ILD may include silicon oxide.

Channel holes CH and contact holes MCH may be formed to penetrate the mold structure MS. The formation of the channel holes CH and the contact holes MCH may include forming a hard mask pattern on the mold structure MS, removing a portion of the mold structure MS through an anisotropic etching process using the hard mask pattern, and removing the hard mask pattern.

On the cell array region CAR, the channel holes CH may be formed to expose the first stop patterns STP1. For example, the channel holes CH may be vertically overlapped with the first stop patterns STP1, respectively. The first stop patterns STP1 may include a material having a higher density than the sacrificial and insulating layers SL and ILD of the mold structure MS. Thus, it may be possible to prevent an over-etching issue in a process of forming the channel holes CH.

On the connection region CCR, the contact holes MCH may be formed to expose the third stop patterns STP3. For example, the contact holes MCH may be vertically overlapped with the third stop patterns STP3, respectively. Similar to the first stop patterns STP1, the third stop patterns STP3 may prevent an over-etching issue in a process of forming the contact holes MCH.

Next, the first and third stop patterns STP1 and STP3 may be selectively removed. The removal of the first and third stop patterns STP1 and STP3 may be performed through an etching process using an etch selectivity between the mold structure MS and the first and third stop patterns STP1 and STP3. The first stop patterns STP1 may be removed through the channel holes CH. The third stop patterns STP3 may be removed through the contact holes MCH. Accordingly, a portion of the carrier substrate 100 may be exposed again.

First sacrificial patterns SP1 may be formed in the contact holes MCH, respectively. The first sacrificial patterns SP1 may have an etch selectivity with respect to the mold structure MS. In the mold structure MS, each of the first sacrificial patterns SP1 may be extended in the third direction D3. Each of the first sacrificial patterns SP1 may be further extended into the second device isolation patterns STI2. The contact holes MCH may not be exposed, and only the channel holes CH may be exposed.

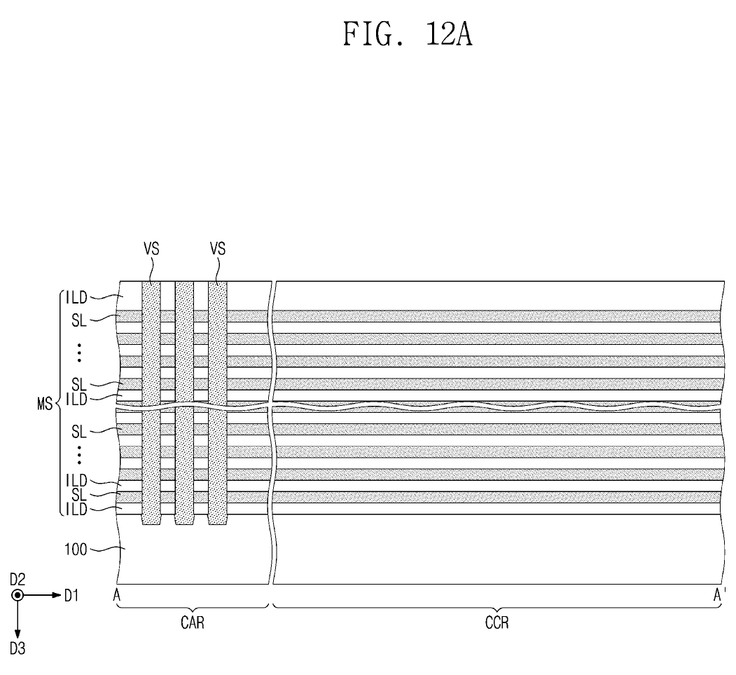

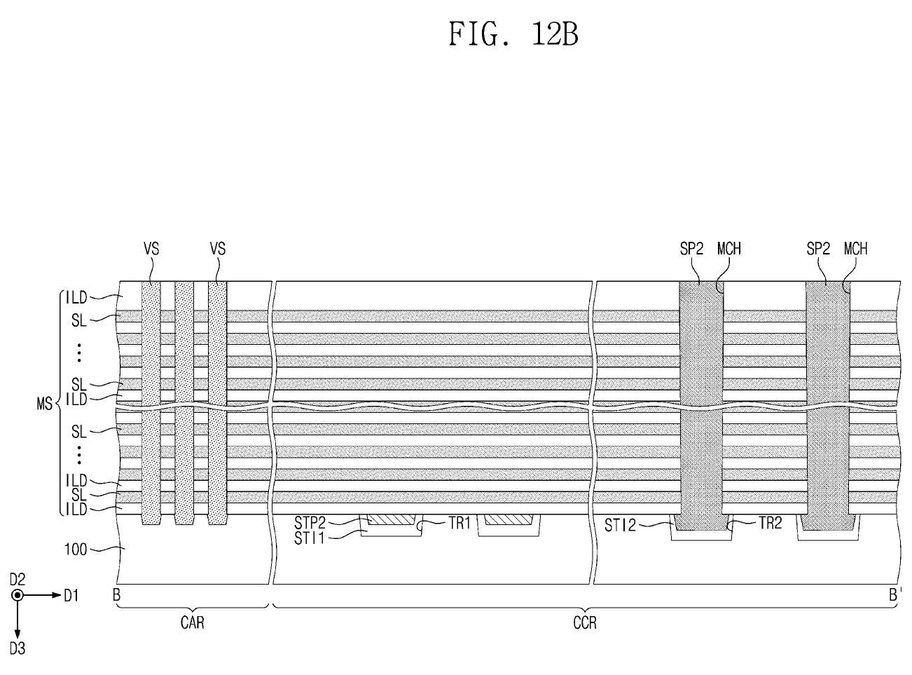

In FIGS. 12A and 12B, the vertical structures VS may be formed in the channel holes CH, respectively. The formation of the vertical structures VS may include sequentially forming the data storage pattern DSP, the vertical semiconductor pattern VP, and the gapfill insulating pattern VI of FIG. 7 in the channel holes CH. Each of the data storage pattern DSP, the vertical semiconductor pattern VP, and the gapfill insulating pattern VI may be formed by a chemical vapor deposition process or an atomic layer deposition process. In some implementations, the dummy vertical structures DVS of FIG. 5 may be formed simultaneously with the vertical structures VS.

Thereafter, the first sacrificial patterns SP1 in the contact holes MCH may be selectively removed. Since the first sacrificial patterns SP1 have an etch selectivity with respect to the mold structure MS, the mold structure MS may not be removed. Accordingly, a side surface of the mold structure MS and the second device isolation patterns STI2 may be re-opened.

After the removal of the first sacrificial patterns SP1, an enlarging process may be performed on the contact holes MCH. For example, the enlarging process may include repeatedly performing an etching process and a deposition process on the contact holes MCH. Accordingly, the mold structure MS and the second device isolation patterns STI2 may be partially removed. As a result, each of the contact holes MCH may have an increased horizontal width and an increased vertical length.

Second sacrificial patterns SP2 may be formed in the enlarged contact holes MCH, respectively. The second sacrificial patterns SP2 may include substantially the same material as the first sacrificial patterns SP1. For example, the second sacrificial patterns SP2 may have an etch selectivity with respect to the mold structure MS.

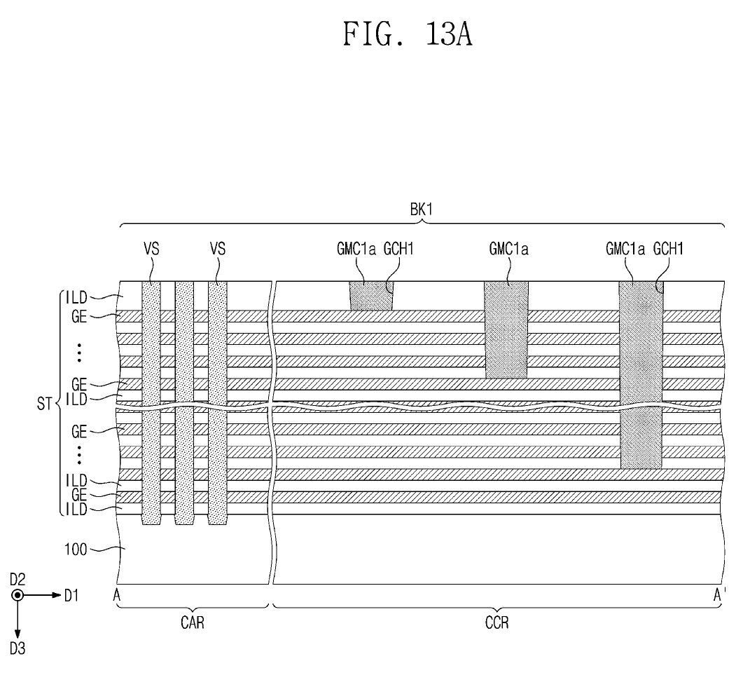

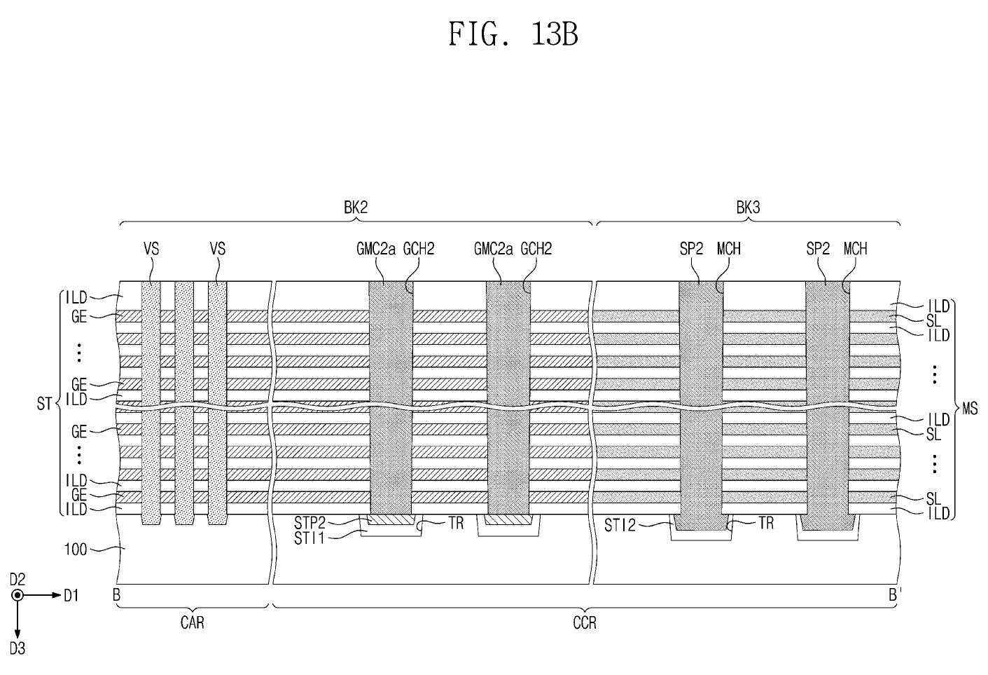

In FIGS. 13A and 13B, first preliminary gate contacts GMC1a and second preliminary gate contacts GMC2a may be formed on the connection region CCR. The first and second preliminary gate contacts GMC1a and GMC2a may be respectively formed in first and second gate contact holes GCH1 and GCH2 penetrating the mold structure MS.

In some implementations, the first gate contact holes GCH1 may be formed to partially penetrate the mold structure MS. The first gate contact holes GCH1 may have different lengths in the third direction D3. In this case, the first preliminary gate contacts GMC1a, which are respectively formed in the first gate contact holes GCH1, may have different lengths from each other in the third direction D3.

The second gate contact holes GCH2 may be formed to penetrate the mold structure MS. The second gate contact holes GCH2 may be formed to have the same length in the third direction D3. The second stop patterns STP2 may include a material having a higher density than the sacrificial and insulating layers SL and ILD of the mold structure MS. Accordingly, it may be possible to prevent an over-etching issue in a process of forming the second gate contact holes GCH2. The second preliminary gate contacts GMC2a, which are formed in the second gate contact holes GCH2, may be in contact with the second stop patterns STP2.

The first and second preliminary gate contacts GMC1a and GMC2a may include substantially the same material as the first and second sacrificial patterns SP1 and SP2 described above. For example, the first and second preliminary gate contacts GMC1a and GMC2a may have an etch selectivity with respect to the mold structure MS. In addition, the first and second preliminary gate contacts GMC1a and GMC2a may have an etch selectivity with respect to the stack ST.

In some implementations, a protection insulating layer may be further formed in the first and second gate contact holes GCH1 and GCH2, before the formation of the first and second preliminary gate contacts GMC1a and GMC2a. The protection insulating layer may cover inner surfaces of the first and second gate contact holes GCH1 and GCH2 with a uniform thickness. The protection insulating layer may be used to protect the first and second preliminary gate contacts GMC1a and GMC2a in a subsequent process of removing the sacrificial layers SL.

Next, the stack ST including the first and second blocks BK1 and BK2 may be formed. The formation of the stack ST may include removing the sacrificial layers SL, which are exposed through a space for forming the separation structures SS described with reference to FIG. 5. The removal of the sacrificial layers SL may be performed through a wet etching process using an etching solution having an etch selectivity. Due to the selective removal of the sacrificial layers SL, the mold structure MS may become structurally weak. Accordingly, the mold structure MS may be collapsed or tilted. In this case, the vertical structures VS, the first and second preliminary gate contacts GMC1a and GMC2a, and the second sacrificial patterns SP2 may support the mold structure MS.

The gate electrodes GE may be formed in empty regions, which are formed by removing the sacrificial layers SL. The gate electrodes GE may be formed to partially or fully fill the empty regions, which are formed by removing the sacrificial layers SL. For example, the formation of the gate electrodes GE may include sequentially depositing a metal nitride layer (e.g., TiN, TaN, or WN) and a metal layer (e.g., W, Al, Ti, Ta, Co, or Cu). Accordingly, the first and second blocks BK1 and BK2 of the stack ST, in which the gate electrodes GE and the insulating layers ILD are alternately stacked, may be formed on the carrier substrate 100. In this case, a portion of the mold structure MS may form the stack ST.

A remaining portion of the mold structure MS, which does not form the stack ST, may form the third block BK3 of the mold structure MS. The separation structures SS of FIG. 5 may not be formed between the second block BK2 of the stack ST and the third block BK3 of the mold structure MS. In this case, since the sacrificial layers SL of the third block BK3 are not exposed, the sacrificial layers SL of the third block BK3 may not be removed.

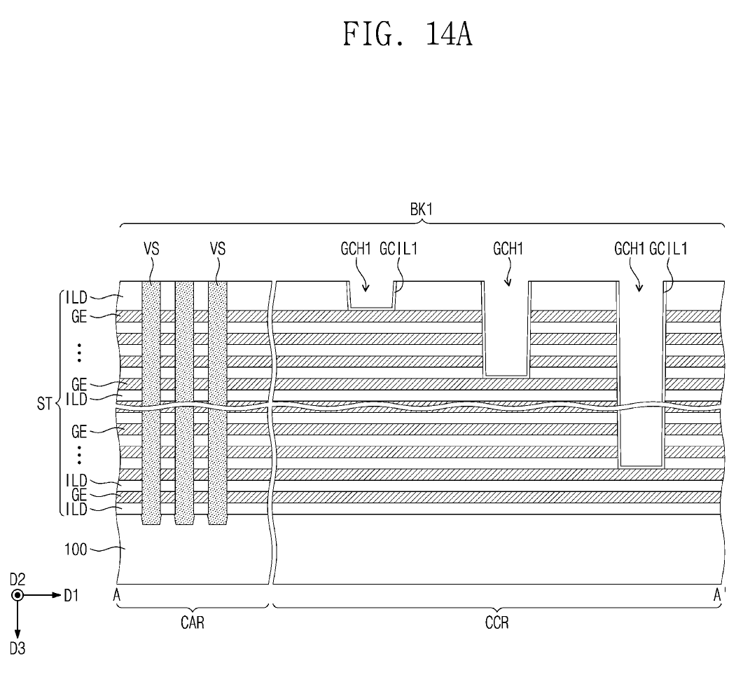

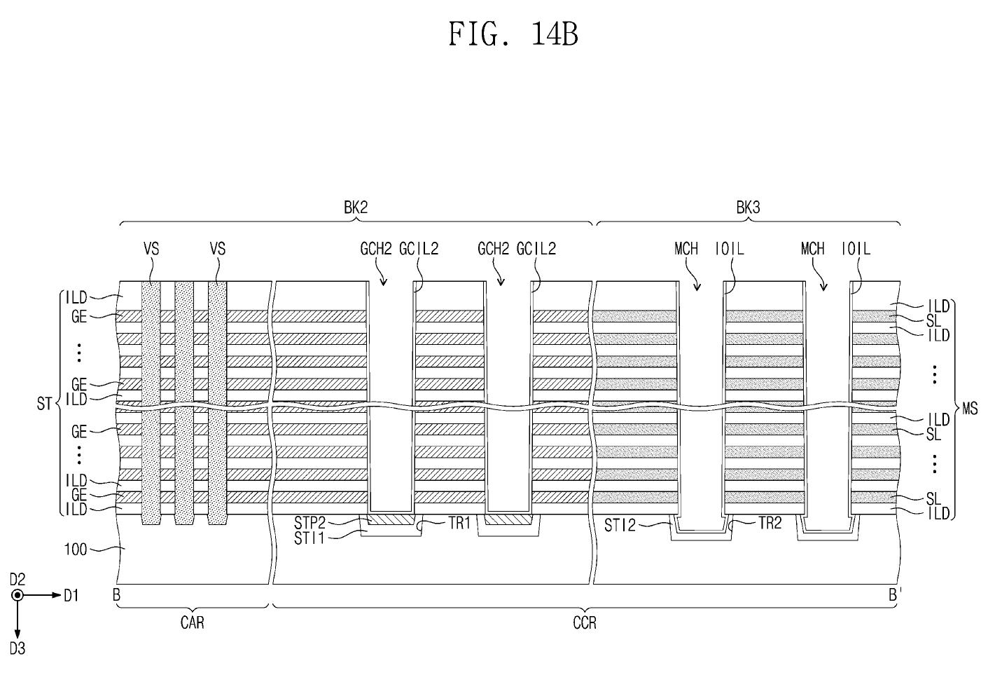

In FIGS. 14A and 14B, the first and second preliminary gate contacts GMC1a and GMC2a and the second sacrificial patterns SP2 may be removed. Since each of the first and second preliminary gate contacts GMC1a and GMC2a and the second sacrificial patterns SP2 has an etch selectively with respect to the mold structure MS and the stack ST, the first and second preliminary gate contacts GMC1a and GMC2a and the second sacrificial patterns SP2 may be selectively removed. The mold structure MS and the stack ST may not be removed, during the removal of the first and second preliminary gate contacts GMC1a and GMC2a and the second sacrificial patterns SP2. Since the first and second preliminary gate contacts GMC1a and GMC2a and the second sacrificial patterns SP2 are removed, the first and second gate contact holes GCH1 and GCH2 and the contact holes MCH may be re-opened. Thus, the side surfaces of the stack ST and the mold structure MS may be exposed again.

In some implementations, the first and second preliminary gate contacts GMC1a and GMC2a and the second sacrificial patterns SP2 may include substantially the same material. Accordingly, the first and second preliminary gate contacts GMC1a and GMC2a and the second sacrificial patterns SP2 may be removed simultaneously through a single process.

Thereafter, a first gate insulating layer GCIL1 may be formed in the first gate contact holes GCH1, a second gate insulating layer GCIL2 may be formed in the second gate contact holes GCH2, and an input/output insulating layer IOIL may be formed in the contact holes MCH. Each of the first and second gate insulating layers GCIL1 and GCIL2 and the input/output insulating layer IOIL may cover an inner surface of each of the first and second gate contact holes GCH1 and GCH2 and the contact holes MCH with a uniform thickness.

More specifically, the first gate insulating layer GCIL1 may be in contact with a portion of one of the gate electrodes GE of the stack ST. The second gate insulating layer GCIL2 may be in contact with top surfaces of the second stop patterns STP2. The input/output insulating layer IOIL may be in contact with inner surface of the second device isolation patterns STI2. In some implementations, the first and second gate insulating layers GCIL1 and GCIL2 and the input/output insulating layer IOIL may include at least one of silicon oxide or low-k dielectric materials.

In some implementations, the first and second gate insulating layers GCIL1 and GCIL2 and the input/output insulating layer IOIL may be formed simultaneously through a single process. Accordingly, the first and second gate insulating layers GCIL1 and GCIL2 and the input/output insulating layer IOIL may include substantially the same material and may have substantially the same thickness.

In FIGS. 15A, 15B, 15C, and FIG. 15D, an etch-back process may be performed on the first and second gate insulating layers GCIL1 and GCIL2 and the input/output insulating layer IOIL. The etch-back process may be performed to remove portions of the first gate insulating layer GCIL1 under bottom surfaces of the first gate contact holes GCH1, portions of the second gate insulating layer GCIL2 under bottom surfaces of the second gate contact holes GCH2, and portions of the input/output insulating layer IOIL under bottom surfaces of the contact holes MCH. As a result of the partial removal of the first and second gate insulating layers GCIL1 and GCIL2 and the input/output insulating layer IOIL, the first and second gate insulating patterns GCIP1 and GCIP2 and the input/output insulating patterns IOIP may be formed at the same time.

In some implementations, the gate electrodes GE of the stack ST and the second stop patterns STP2 may include a material having a higher density than the first and second gate insulating layers GCIL1 and GCIL2, the input/output insulating layer IOIL, and the second device isolation patterns STI2. Accordingly, the gate electrodes GE and the second stop patterns STP2 may not be etched by the etch-back process or may be less etched. By contrast, the second device isolation patterns STI2 may be partially etched by the etch-back process, along with the input/output insulating layer IOIL. Accordingly, recess regions RS may be formed to extend from the bottom surfaces of the contact holes MCH into the second device isolation patterns STI2.

Next, the first gate contacts GMC1 may be formed to fill the first gate contact holes GCH1, the second gate contacts GMC2 may be formed to fill the second gate contact holes GCH2, and the input/output contacts IOMC may be formed to fill the contact holes MCH. The formation of the first and second gate contacts GMC1 and GMC2 and the input/output contacts IOMC may include filling the first and second gate contact holes GCH1 and GCH2 and the contact holes MCH with a metallic material and performing a planarization process on the metallic material.

In some implementations, the first and second gate contacts GMC1 and GMC2 and the input/output contacts IOMC may be formed at the same time. In this case, top surfaces GMC1U of the first gate contacts GMC1, top surfaces GMC2U of the second gate contacts GMC2, and top surfaces IOMCU of the input/output contacts IOMC may be substantially coplanar with each other. The top surfaces GMC1U of the first gate contacts GMC1, the top surfaces GMC2U of the second gate contacts GMC2, and the top surfaces IOMCU of the input/output contacts IOMC may be placed at the same level as the first surface STa of the stack ST and the third surface MSa of the mold structure MS. That is, the first and second gate contacts GMC1 and GMC2 and the input/output contacts IOMC may be aligned along the first surface STa of the stack ST and the third surface MSa of the mold structure MS.

More specifically, each of the second gate contacts GMC2 may include the first portion P1 and the second portion P2 on the first portion P1. For example, the first portion P1 may correspond to each of the second stop patterns STP2. The first and second portions P1 and P2 may be formed through different processes but may be formed of substantially the same material. In this case, there may be no visible interface between the first and second portions P1 and P2.

Each of the input/output contacts IOMC may include the third portion P3 and the fourth portion P4 on the third portion P3. Each of the input/output contacts IOMC may further include a protruding portion PP, which is extended from the third portion P3 toward the second device isolation patterns STI2. For example, the protruding portion PP may be placed in the recess regions RS. The third portion P3, the fourth portion P4, and the protruding portion PP of each of the input/output contacts IOMC may be formed at the same time, and there may be no visible interface therebetween.

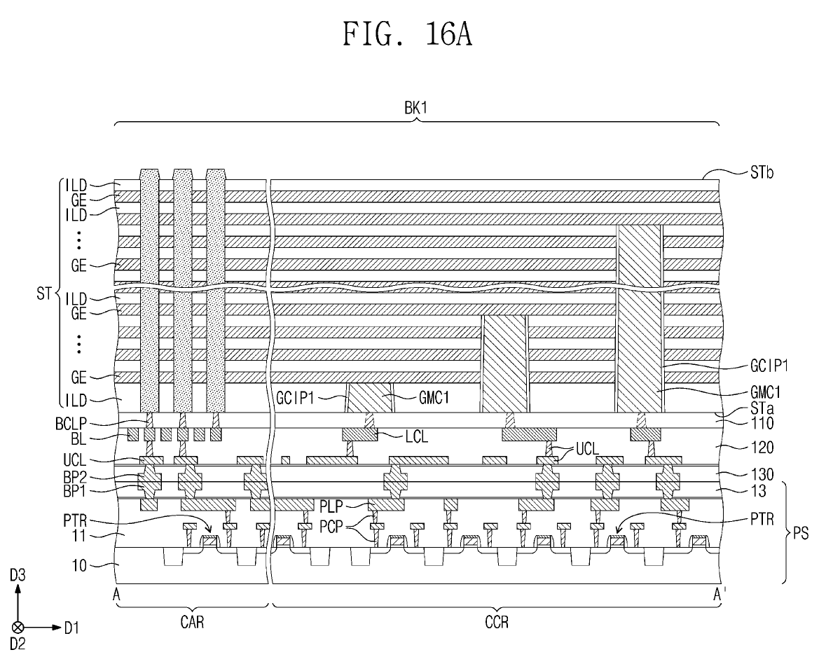

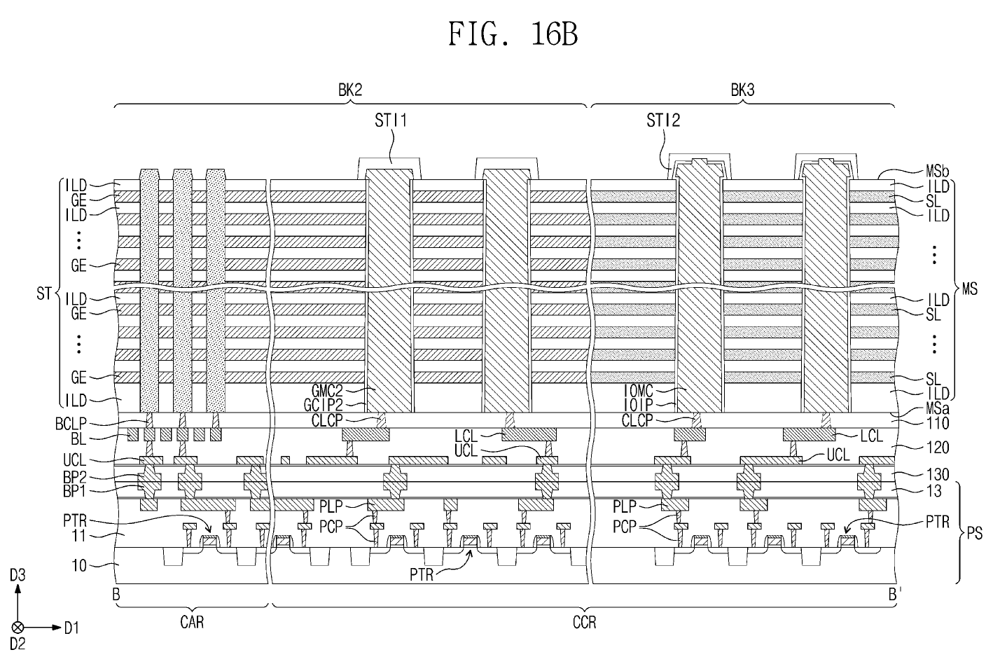

In FIGS. 16A and 16B, the first to third interlayer insulating layers 110, 120, and 130 may be sequentially formed on the first surface STa of the stack ST and the third surface MSa of the mold structure MS. The bit line plugs BLCP, which are connected to the vertical structures VS, and the conductive line plugs CLCP, which are connected to the first and second gate contacts GMC1 and GMC2 and the input/output contacts IOMC, may be formed in the first interlayer insulating layer 110.

The bit lines BL, the lower conductive lines LCL, and the upper conductive lines UCL may be formed in the second interlayer insulating layer 120. The formation of the bit lines BL, the lower conductive lines LCL, and the upper conductive lines UCL may include patterning the second interlayer insulating layer 120 and filling the patterned regions of the second interlayer insulating layer 120 with a conductive material. The bit lines BL may be connected to the bit line plugs BLCP, and the lower conductive lines LCL may be connected to the conductive line plugs CLCP.

The second bonding pads BP2 may be formed in the third interlayer insulating layer 130. The formation of the second bonding pads BP2 may include performing a planarization process on the third interlayer insulating layer 130. As a result, surfaces of the second bonding pads BP2 may be exposed to the outside. The second bonding pads BP2 may be connected to the upper conductive lines UCL.

Next, the peripheral circuit structure PS may be formed. The formation of the peripheral circuit structure PS may include forming the peripheral transistors PTR on the active regions of the substrate 10, forming the peripheral plugs PCP and the peripheral circuit lines PLP, which are electrically connected to the peripheral transistors PTR, forming the first lower insulating layer 11 to cover the peripheral transistors PTR, the peripheral plugs PCP, and the peripheral circuit lines PLP, forming the first bonding pads BP1 connected to the peripheral circuit lines PLP, and forming the second lower insulating layer 13 to enclose the first bonding pads BP1.

The peripheral circuit structure PS may be bonded to the third interlayer insulating layer 130. More specifically, the first bonding pads BP1 of the peripheral circuit structure PS may be in contact with and boned to the second bonding pads BP2 in the third interlayer insulating layer 130. During this process, the carrier substrate 100 may be inverted. Accordingly, the first surface STa of the stack ST may be placed below the second surface STb. The third surface MSa of the mold structure MS may be placed below the fourth surface MSb.

Thereafter, the carrier substrate 100 may be removed. The removal of the carrier substrate 100 may include one of a grinding process, a planarization process, and an etching process. As a result of the removal of the carrier substrate 100, the vertical structures VS, the first and second device isolation patterns STI1 and STI2, the second surface STb of the stack ST, and the fourth surface MSb of the mold structure MS may be partially exposed.

During the removal of the carrier substrate 100, the second gate contacts GMC2 and the input/output contacts IOMC may not be exposed to the outside by the first and second device isolation patterns STI1 and STI2. That is, the first and second device isolation patterns STI1 and STI2 may protect corresponding ones of the second gate contacts GMC2 and the input/output contacts IOMC. In this case, it may be possible to prevent the second gate contacts GMC2 and the input/output contacts IOMC from being damaged.

After the removal of the carrier substrate 100, the data storage pattern DSP of each of the vertical structures VS may be partially removed, as described with reference to FIG. 7. Accordingly, the vertical semiconductor pattern VP of each of the vertical structures VS may be exposed to the outside.

In FIGS. 6A and 6B, the source structure CST may be formed on the cell array region CAR. Next, the first upper insulating layer UIL1 may be formed to cover the source structure CST, the stack ST, and the mold structure MS.

The via patterns VA may be formed in the first upper insulating layer UIL1. The via patterns VA may be formed to penetrate the first upper insulating layer UIL1 and the first and second device isolation patterns STI1 and STI2. The via patterns VA may be connected to the second gate contacts GMC2 and the input/output contacts IOMC, respectively. Due to the via patterns VA, the protruding portion PP (e.g., see FIG. 15D) of each of the input/output contacts IOMC may not be visible.

Next, the input/output pads PAD may be formed on the first upper insulating layer UIL1. The second upper insulating layer UIL2, the protection layer PTL, and the passivation layer PAS may be sequentially formed on the first upper insulating layer UIL1 to cover the input/output pads PAD. The second upper insulating layer UIL2, the protection layer PTL, and the passivation layer PAS may be partially removed to form the openings OP exposing the input/output pads PAD.

In some implementations, the first and second preliminary gate contacts GMC1a and GMC2a and the second sacrificial patterns SP2 may be removed at the same time, and the first and second gate insulating patterns GCIP1 and GCIP2 and the input/output insulating patterns IOIP may be formed at the same time. In addition, the first and second gate contacts GMC1 and GMC2 and the input/output contacts IOMC may be formed at the same time. Accordingly, it may be possible to simplify a process of fabricating a three-dimensional semiconductor memory device.

In some implementations, gate contacts in a dummy block may be configured to execute substantially the same function as input/output contacts connecting an input/output pad to a peripheral circuit structure. Accordingly, electrical signals and voltages may be easily transmitted to the three-dimensional semiconductor memory device. Accordingly, the electrical characteristics of the three-dimensional semiconductor memory device may be improved.

In addition, in some implementations, first gate insulating patterns, second gate insulating patterns, and input/output insulating patterns may be formed at the same time, and first gate contacts, second gate contacts, and input/output contacts may be formed at the same time. Accordingly, a process of fabricating a three-dimensional semiconductor memory device may be simplified.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A three-dimensional (3D) semiconductor memory device comprising:
a substrate including a cell array region and a connection region;
a stack including insulating layers and gate electrodes;
a vertical structure on the cell array region, the vertical structure extending into the stack;
a gate contact on the connection region, the gate contact extending into the stack;
an upper insulating layer on the stack; and
a device isolation pattern in the upper insulating layer,
wherein the gate contact extends into at least a portion of the device isolation pattern.

2. The 3D semiconductor memory device of claim 1,
wherein the stack extends in a first direction parallel to a top surface of the substrate, and
wherein the insulating layers and the gate electrodes have a same length in the first direction.

3. The 3D semiconductor memory device of claim 1, comprising an input/output pad on the upper insulating layer,
wherein the gate contact is electrically connected to the input/output pad.

4. The 3D semiconductor memory device of claim 3, comprising a peripheral circuit structure between the substrate and the stack,
wherein the peripheral circuit structure include a peripheral transistor, and
wherein the input/output pad and the peripheral transistor are electrically connected to each other by the gate contact.

5. The 3D semiconductor memory device of claim 1, comprising a gate insulating pattern between the stack and the gate contact,
wherein the stack and the gate contact are electrically insulated from each other by the gate insulating pattern.

6. The 3D semiconductor memory device of claim 1, wherein the gate contact comprises:
a first portion in the device isolation pattern; and
a second portion in the stack,
wherein a width of the second portion adjacent to the first portion is smaller than a width of the first portion.

7. The 3D semiconductor memory device of claim 1, comprising a source structure provided on the stack and on the cell array region,
wherein the source structure contacts the vertical structure.

8. A three-dimensional (3D) semiconductor memory device comprising:
a substrate including a cell array region and a connection region that extends from the cell array region in a first direction;
a stack on the substrate, the stack comprising a first block, a second block that are spaced apart from each other in a second direction crossing the first direction;
vertical structures on the cell array region, the vertical structures extending into the stack;
an upper insulating layer on the stack;
a first gate contact on the connection region, the first gate contact extending into the first block of the stack; and
a second gate contact on the connection region, the second gate contact extending into the second block of the stack,
wherein a length of the second gate contact is larger than a length of the stack in a third direction crossing the first direction and the second direction.

9. The 3D semiconductor memory device of claim 8, wherein a length of the first gate contact in the third direction is smaller than the length of the stack in the third direction.

10. The 3D semiconductor memory device of claim 8, comprising:
a third block of a mold structure spaced apart from the first block of the stack in the second direction, the second block of the stack being disposed between the first block and the third block, and the third block extending in the first direction; and
an input/output contact extending into the third block of the mold structure.

11. The 3D semiconductor memory device of claim 10,
wherein the stack comprises insulating layers and gate electrodes that are alternately stacked on the substrate, and
wherein the mold structure comprises the insulating layers and sacrificial layers that are alternately stacked on the substrate.

12. The 3D semiconductor memory device of claim 10, comprising a first device isolation pattern and a second device isolation pattern in the upper insulating layer,
wherein the upper insulating layer covers the stack and the mold structure.

13. The 3D semiconductor memory device of claim 12,
wherein the second gate contact comprises a first portion in the first device isolation pattern and a second portion in the second block of the stack,
wherein the input/output contact comprises a third portion in the second device isolation pattern and a fourth portion in the third block of the mold structure, and
wherein a thickness of the first portion in the third direction is smaller than a thickness of the third portion in the third direction.

14. The 3D semiconductor memory device of claim 12, wherein a depth of the first device isolation pattern in the third direction is smaller than a depth of the second device isolation pattern in the third direction.

15. The 3D semiconductor memory device of claim 12, comprising:
a gate insulating pattern between the second gate contact and the stack; and
an input/output insulating pattern between the input/output contact and the mold structure,
wherein the input/output insulating pattern extends into a region between the input/output contact and the second device isolation pattern.

16. The 3D semiconductor memory device of claim 12, comprising:
input/output pads on the upper insulating layer; and
via patterns connecting the input/output pads to the second gate contact and the input/output contact,
wherein the via patterns extend into the first device isolation pattern and the second device isolation pattern, respectively.

17. The 3D semiconductor memory device of claim 12,
wherein the input/output contact comprises a plurality of input/output contacts,
wherein the second device isolation pattern comprises a plurality of second device isolation patterns, and
wherein the plurality of second device isolation patterns are connected to each other.

18. An electronic system comprising:
a three-dimensional semiconductor memory device including input/output pads electrically connected to peripheral transistors; and
a controller electrically connected to the three-dimensional semiconductor memory device through the input/output pads and configured to control the three-dimensional semiconductor memory device,
wherein the three-dimensional semiconductor memory device comprises:
a substrate including a cell array region and a connection region;
a stack including gate electrodes on the substrate;
vertical structures on the cell array region, the vertical structures extending into the stack; and
a first gate contact and a second gate contact on the connection region of the substrate,
wherein the first gate contact extends into the stack and is connected to one of the gate electrodes,
wherein the second gate contact extends into the stack and is connected to one of the input/output pads, and
wherein the first gate contact and the second gate contact are aligned along a first surface of the stack.

19. The electronic system of claim 18, comprising:
a device isolation pattern on the stack; and
an upper insulating layer covering the stack and the device isolation pattern,
wherein the second gate contact extends into the device isolation pattern and is spaced apart from the upper insulating layer.

20. The electronic system of claim 18, comprising:
a mold structure adjacent to the stack; and
an input/output contact extending into the mold structure and connecting another one of the input/output pads to the peripheral transistors.
